(19) United States
(12) Patent Application Publication
(10) Pub. No.: US 2024/0086593 A1
(43) Pub. Date: Mar. 14, 2024

(54) USING FABRICATION MODELS BASED ON LEARNED MORPHOLOGICAL OPERATIONS FOR DESIGN AND FABRICATION OF PHYSICAL DEVICES

(71) Applicant: X Development LLC, Mountain View, CA (US)

(72) Inventors: Ian Williamson, Palo Alto, CA (US); Alfred Ka Chun Cheung, Belmont, CA (US); Martin Schubert, Mountain View, CA (US)

(21) Appl. No.: 17/891,846

(22) Filed: Aug. 19, 2022

(51) Int. Cl. G06F 30/27; G06F 30/367

(52) U.S. Cl. CPC G06F 30/27; G06F 30/367

(57) ABSTRACT

In some embodiments, techniques for optimizing a design for a physical device to be fabricated by a fabrication system is provided. A computing system receives an initial design. The computing system uses a fabrication model to determine structural parameters based on the initial design, wherein using the fabrication model includes applying one or more morphological transformations to the initial design that are predicted to be introduced by the fabrication system. The computing system obtains a performance metric by simulating performance of the structural parameters. The computing system determines a loss metric based on the performance metric. The computing system backpropagates a gradient of the loss metric to generate an updated design.

### TECHNICAL FIELD

This disclosure relates generally to the design of physical devices for fabrication, and in particular but not exclusively, relates to photonic devices including but not limited to optical multiplexers and demultiplexers.

### BACKGROUND

Fiber-optic communication is typically employed to transmit information from one place to another via light that has been modulated to carry the information. For example, many telecommunication companies use optical fiber to transmit telephone signals, internet communication, and cable television signals. But the cost of deploying optical fibers for fiber-optic communication may be prohibitive. As such, techniques have been developed to more efficiently use the bandwidth available within a single optical fiber. Wavelength-division multiplexing is one such technique that bundles multiple optical carrier signals onto a single optical fiber using different wavelengths. Fabrication techniques used to create physical devices such as photonic devices for use in these contexts can create complex physical structures, but a fabricated physical device may differ from the design of the physical device due to specifics of the fabrication process as implemented by a particular fabrication system.

### BRIEF SUMMARY

In some embodiments, a non-transitory computer-readable medium is provided. The computer-readable medium has computer-executable instructions stored thereon that, in response to execution by one or more processors of a computing system, cause the computing system to perform actions for optimizing a design for a physical device to be fabricated by a fabrication system. The actions comprise receiving, by the computing system, an initial design; using, by the computing system, a fabrication model to determine structural parameters based on the initial design, wherein using the fabrication model includes applying one or more morphological transformations to the initial design that are predicted to be introduced by the fabrication system; obtaining, by the computing system, a performance metric by simulating performance of the structural parameters; determining, by the computing system, a loss metric based on the performance metric; and backpropagating a gradient of the loss metric to generate an updated design.

In some embodiments, a computer-implemented method for optimizing a design for a physical device to be fabricated by a fabrication system is provided. A computing system receives an initial design. The computing system uses a fabrication model to determine structural parameters based on the initial design, wherein using the fabrication model includes applying one or more morphological transformations to the initial design that are predicted to be introduced by the fabrication system. The computing system obtains a performance metric by simulating performance of the structural parameters. The computing system determines a loss metric based on the performance metric. The computing system backpropagates a gradient of the loss metric to generate an updated design.

### BRIEF DESCRIPTION OF THE SEVERAL VIEWS OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described. To easily identify the discussion of any particular element or act, the most significant digit or digits in a reference number refer to the figure number in which that element is first introduced.

FIG. 1 is a functional block diagram illustrating a non-limiting example embodiment of a system for optical communication between two optical communication devices via an optical signal, according to various aspects of the present disclosure.

FIG. 2A and FIG. 2B respectively illustrate a non-limiting example embodiment of a demultiplexer and multiplexer, according to various aspects of the present disclosure.

FIG. 2C illustrates a non-limiting example embodiment of a distinct wavelength channel of a multi-channel optical signal, according to various aspects of the present disclosure.

FIG. 3A-FIG. 3D illustrate different views of a non-limiting example embodiment of a photonic demultiplexer, according to various aspects of the present disclosure.

FIG. 4A and FIG. 4B illustrate a more detailed cross-sectional view of a dispersive region of a non-limiting example embodiment of a photonic demultiplexer, according to various aspects of the present disclosure.

FIG. 5 is a functional block diagram illustrating a non-limiting example embodiment of a system for generating a design of a photonic integrated circuit, according to various aspects of the present disclosure.

FIG. 6A illustrates a non-limiting example embodiment of a virtual prototype describing a photonic integrated circuit, according to various aspects of the present disclosure.

FIG. 6B illustrates a non-limiting example embodiment of an operational simulation of a photonic integrated circuit, according to various aspects of the present disclosure.

FIG. 6C illustrates a non-limiting example embodiment of an adjoint simulation within the virtual prototype by backpropagating a loss value, according to various aspects of the present disclosure.

FIG. 7A is a flow chart illustrating example time steps for an operational simulation and an adjoint simulation, in accordance with various aspects of the present disclosure.

FIG. 7B is a chart illustrating the relationship between the update operation for the operational simulation and the adjoint simulation (e.g., backpropagation), in accordance with an embodiment of the present disclosure.

FIG. 8 is a flowchart that illustrates a non-limiting example embodiment of a method of designing a physical device, in accordance with various aspects of the present disclosure.

FIG. 9 is an illustration of a portion of a fabricated photonic device and its associated design that shows distortions introduced by the fabrication process.

FIG. 10 is a schematic illustration of a non-limiting example embodiment of a fabrication model for simulating a fabrication process as a combination of morphological operations according to various aspects of the present disclosure.

FIG. 11 is a flowchart that illustrates a non-limiting example embodiment of a procedure for training a fabrication model to represent morphological transformations to a design produced by a fabrication system during fabrication according to various aspects of the present disclosure.

### DETAILED DESCRIPTION

In some embodiments of the present disclosure, techniques for designing and fabricating physical devices, including but not limited to photonic devices such as optical communication devices, are provided that use fabrication models that represent morphological transformations to an intended design induced by a fabrication system to improve the accuracy of performance simulations and thereby improve the performance of the fabricated physical device.

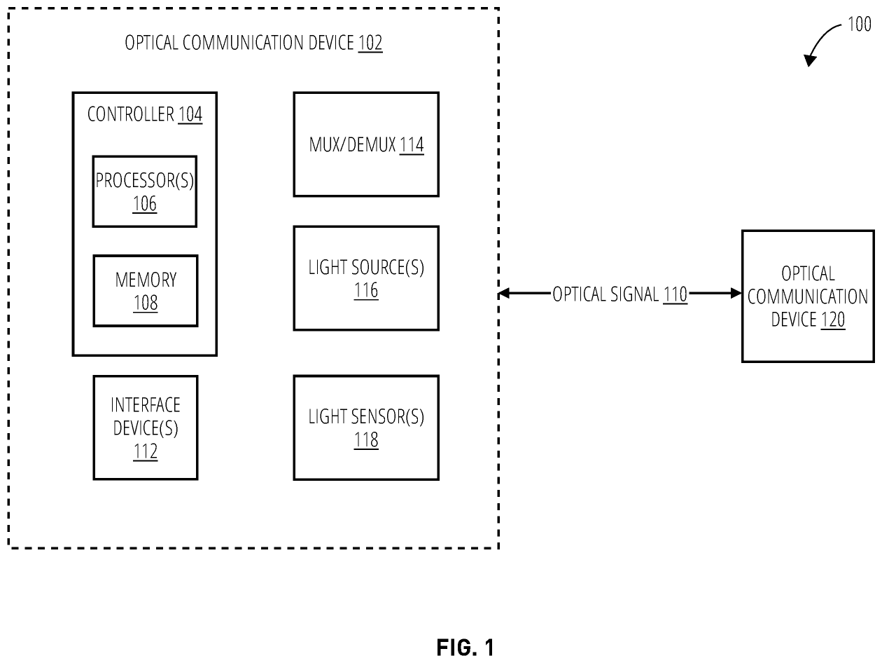

FIG. 1 is a functional block diagram illustrating a system 100 for optical communication (e.g., via wavelength division multiplexing or other techniques) between optical communication device 102 and optical communication device 120 via optical signal 110, in accordance with various aspects of the present disclosure. More generally, optical communication device 102 is configured to transmit information by modulating light from one or more light sources into a multi-channel optical signal 110 (e.g., a singular optical signal that includes a plurality of distinct wavelength channels) that is subsequently transmitted from optical communication device 102 to optical communication device 120 via an optical fiber, a light guide, a wave guide, or other photonic device. Optical communication device 120 receives the multi-channel optical signal 110 and demultiplexes each of the plurality of distinct wavelength channels from the multi-channel optical signal 110 to extract the transmitted information. It is appreciated that in some embodiments optical communication device 102 and optical communication device 120 may be distinct and separate devices (e.g., an optical transceiver or transmitter communicatively coupled via one or more optical fibers to a separate optical transceiver or receiver). However, in other embodiments, optical communication device 102 and optical communication device 120 may be part of a singular component or device (e.g., a smartphone, a tablet, a computer, optical device, or the like). For example, optical communication device 102 and optical communication device 120 may both be constituent components on a monolithic integrated circuit that are coupled to one another via a waveguide that is embedded within the monolithic integrated circuit and is adapted to carry optical signal 110 between optical communication device 102 and optical communication device 120 or otherwise transmit the optical signal between one place and another.

In the illustrated embodiment, optical communication device 102 includes a controller 104, one or more interface device(s) 112 (e.g., fiber optic couplers, light guides, waveguides, and the like), a multiplexer (mux), demultiplexer (demux), or combination thereof (MUX/DEMUX 114), one or more light source(s) 116 (e.g., light emitting diodes, lasers, and the like), and one or more light sensor(s) 118 (e.g., photodiodes, phototransistors, photoresistors, and the like) coupled to one another. The controller includes one or more processor(s) 106 (e.g., one or more central processing units, application specific circuits, field programmable gate arrays, or otherwise) and memory 108 (e.g., volatile memory such as DRAM and SAM, non-volatile memory such as ROM, flash memory, and the like). It is appreciated that optical communication device 120 may include the same or similar elements as optical communication device 102, which have been omitted for clarity.

Controller 104 orchestrates operation of optical communication device 102 for transmitting and/or receiving optical signal 110 (e.g., a multi-channel optical signal having a plurality of distinct wavelength channels or otherwise). Controller 104 includes software (e.g., instructions included in memory 108 coupled to processor 106) and/or hardware logic (e.g., application specific integrated circuits, field-programmable gate arrays, and the like) that when executed by controller 104 causes controller 104 and/or optical communication device 102 to perform operations.

In one embodiment, controller 104 may choreograph operations of optical communication device 102 to cause light source(s) 116 to generate a plurality of distinct wavelength channels that are multiplexed via MUX/DEMUX 114 into a multi-channel optical signal 110 that is subsequently transmitted to optical communication device 120 via interface device 112. In other words, light source(s) 116 may output light having different wavelengths (e.g., 1271 nm, 1291 nm, 1311 nm, 1331 nm, 1506 nm, 1514 nm, 1551 nm, 1571, or otherwise) that may be modulated or pulsed via controller 104 to generate a plurality of distinct wavelength channels representative of information. The plurality of distinct wavelength channels are subsequently combined or otherwise multiplexed via MUX/DEMUX 114 into a multi-channel optical signal 110 that is transmitted to optical communication device 120 via interface device 112. In the same or another embodiment, controller 104 may choreograph operations of optical communication device 102 to cause a plurality of distinct wavelength channels to be demultiplexed via MUX/DEMUX 114 from a multi-channel optical signal 110 that is received via interface device 112 from optical communication device 120.

It is appreciated that in some embodiments certain elements of optical communication device 102 and/or optical communication device 120 may have been omitted to avoid obscuring certain aspects of the disclosure. For example, optical communication device 102 and optical communication device 120 may include amplification circuitry, lenses, or components to facilitate transmitting and receiving optical signal 110. It is further appreciated that in some embodiments optical communication device 102 and/or optical communication device 120 may not necessarily include all elements illustrated in FIG. 1. For example, in one embodiment optical communication device 102 and/or optical communication device 120 are passive devices that operate as an intermediary device that may passively multiplex a plurality of distinct wavelength channels into a multi-channel optical signal 110 and/or demultiplex a plurality of distinct wavelength channels from a multi-channel optical signal 110.

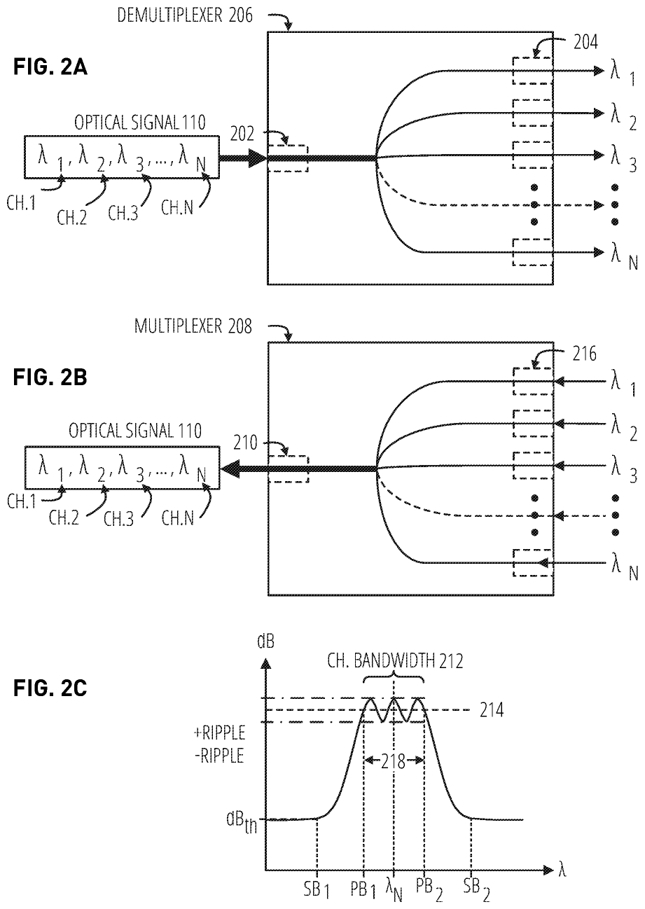

FIG. 2A and FIG. 2B respectively illustrate an example demultiplexer 206 and multiplexer 208, in accordance with various aspects of the present disclosure. Demultiplexer 206 and multiplexer 208 are possible embodiments of MUX/DEMUX 114 illustrated in FIG. 1, and which may be part of an integrated photonic circuit, silicon photonic device, or otherwise

As illustrated in FIG. 2A, demultiplexer 206 includes an input region 202 and a plurality of output regions 204. Demultiplexer 206 is configured to receive a multi-channel optical signal 110 that includes a plurality of distinct wavelength channels (e.g., Ch. 1, Ch. 2, Ch. 3, . . . Ch. N, each having a center wavelength respectively corresponding to λ₁, λ₂, λ₃, . . . λ_{N}) via input region 202 (e.g., a waveguide that may correspond to interface device 112 illustrated in FIG. 1) to optically separate each of the plurality of distinct wavelength channels from the multi-channel optical signal 110 and respectively guide each of the plurality of distinct wavelength channels to a corresponding one of a plurality of output regions 204 (e.g., a plurality of waveguides that may correspond to interface device(s) 112 illustrated in FIG. 1). More specifically, in the illustrated embodiment, each of the output regions 204 receives a portion of the multi-channel optical signal that corresponds to, or is otherwise representative of, one of the plurality of distinct wavelength channels that may be output as plurality of optical signals (e.g., λ₁, λ₂, λ₃, . . . λ₄). Each output region 204 may be coupled to a respective light sensor (e.g., corresponding to light sensor(s) 118 illustrated in FIG. 1), which may be utilized to convert the optical signals demultiplexed from the multi-channel optical signal 110 into electrical signals for further processing.

In the illustrated embodiment of FIG. 2B, multiplexer 208 includes a plurality of input regions 216 and an output region 210. Multiplexer 208 is configured to receive a plurality of distinct optical signals (e.g., λ₁, λ₂, λ₃, . . . λ_{N}), each at a respective one of the plurality of input regions 216 (e.g., a plurality of waveguides that may correspond to interface device(s) 112 illustrated in FIG. 1). Multiplexer 208 is structured or otherwise configured to optically combine (i.e., multiplex) each of the plurality of distinct wavelength channels into a multi-channel optical signal 110 that is guided to output region 210 (e.g., a waveguide that may correspond to interface device 112 illustrated in FIG. 1). It is appreciated that in some embodiments, demultiplexer 206 illustrated in FIG. 2A and multiplexer 208 illustrated in FIG. 2B may be bidirectional such that each device may function as both a demultiplexer and multiplexer.

FIG. 2C illustrates an example distinct wavelength channel of a multi-channel optical signal (e.g., Ch. N is multi-channel optical signal 110 illustrated in FIG. 1, FIG. 2A, and FIG. 2B), in accordance with various aspects of the present disclosure. The example channel may be representative of an individual channel included in a plurality of distinct wavelength channels of the multi-channel optical signal that may be demultiplexed and/or multiplexed by demultiplexer 206 of FIG. 2A and/or multiplexer 208 of FIG. 2B. Each of the distinct wavelength channels may have different center wavelengths (λ_{N}) including at least one of 1271 nm, 1291 nm, 1311 nm, 1331 nm, 1506 nm, 1514 nm, 1551 nm, or 1571 nm, or otherwise. In the illustrated embodiment of FIG. 2C, the distinct wavelength channel has a channel bandwidth 212 of approximately 13 nm wide. However, in other embodiments the channel bandwidth may be different than 13 nm wide. Rather, the channel bandwidth may be considered a configurable parameter that is dependent upon the structure of MUX/DEMUX 114 of FIG. 1, demultiplexer 206 of FIG. 2A, and/or multiplexer 208 of FIG. 2B. For example, in some embodiments each of the plurality of distinct wavelength channels may share a common bandwidth that may correspond to 13 nm or otherwise. Referring back to FIG. 2C, the channel bandwidth 212 may be defined as the width of a passband region 218 (i.e., the region defined as being between PB₁ and PB₂). The passband region 218 may represent an approximate power transmission of a demultiplexer or multiplexer. It is appreciated that in some embodiments the passband region 218 may include ripple as illustrated in FIG. 2C, which corresponds to fluctuations within the passband region 218. In one or more embodiments, the ripple within the passband region around a central value 214 may be +/−2 dB or less, +/−1 dB or less, +/−0.5 dB or less, or otherwise. In some embodiments, the channel bandwidth 212 may be defined by the passband region 218. In other embodiments, the channel bandwidth 212 may be defined as the measured power above a threshold (e.g., dBₜₕ). For example, demultiplexer 206 illustrated in FIG. 2A may optically separate channel N from multi-channel optical signal 110 and have a corresponding channel bandwidth for channel N equivalent to the range of wavelengths above a threshold value that are transmitted to the output region 204 mapped to channel N (i.e., λ_{N}). In the same or other embodiments, isolation of the channel (i.e., defined by channel bandwidth 212) may also be considered when optimizing the design. The isolation may be defined as a ratio between the passband region 218 and the stopband regions (e.g., regions less than SB₁ and greater than SB₂). It is further appreciated that transition band regions (e.g., a first transition region between SB₁ and PB₁ and a second transition region between PB₂ and SB₂) are exemplary and may be exaggerated for the purposes of illustration. In some embodiments, optimization of the design of the photonic demultiplexer may also include a target metric for a slope, width, or the like of the transition band regions.

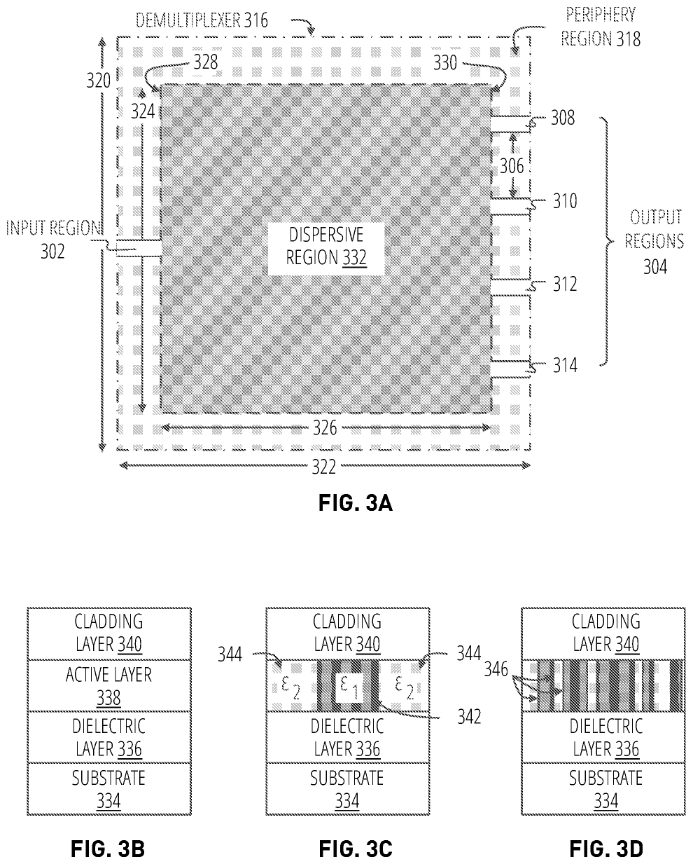

FIG. 3A-FIG. 3D illustrate different views of an example photonic demultiplexer, in accordance with an embodiment of the present disclosure. Photonic demultiplexer 316 is one possible implementation of MUX/DEMUX 114 illustrated in FIG. 1 and demultiplexer 206 illustrated in FIG. 2A. It is further appreciated that while discussion henceforth may be directed towards photonic integrated circuits capable of demultiplexing a plurality of distinct wavelength channels from a multi-channel optical signal, that in other embodiments, a demultiplexer (e.g., demultiplexer 316) may also or alternatively be capable of multiplexing a plurality of distinct wavelength channels into a multi-channel optical signal, in accordance with embodiments of the present disclosure.

FIG. 3A illustrates a cross-sectional view of demultiplexer 316 along a lateral plane within an active layer defined by a width 320 and a length 322 of the demultiplexer 316. As illustrated, demultiplexer 316 includes an input region 302 (e.g., comparable to input region 202 illustrated in FIG. 2A), a plurality of output regions 304 (e.g., comparable to plurality of output regions 204 illustrated in FIG. 2A), and a dispersive region optically disposed between the input region 302 and plurality of output regions 304. The input region 302 and plurality of output regions 304 (e.g., output region 308, output region 310, output region 312, and output region 314) may each be waveguides (e.g., slab waveguide, strip waveguide, slot waveguide, or the like) capable of propagating light along the path of the waveguide. The dispersive region 332 includes a first material and a second material (see, e.g., FIG. 3D) inhomogeneously interspersed to form a plurality of interfaces that each correspond to a change in refractive index of the dispersive region 332 and collectively structure the dispersive region 332 to optically separate each of a plurality of distinct wavelength channels (e.g., Ch. 1, Ch. 2, Ch. 3, . . . Ch. N illustrated in FIG. 2A) from a multi-channel optical signal (e.g., optical signal 110 illustrated in FIG. 2A) and respectively guide each of the plurality of distinct wavelength channels to a corresponding one of the plurality of output regions 304 when the input region 302 receives the multi-channel optical signal. In other words, input region 302 is adapted to receive the multi-channel optical signal including a plurality of distinct wavelength channels and the plurality of output regions 304 are adapted to each receive a corresponding one of the plurality of distinct wavelength channels demultiplexed from the multi-channel optical signal via dispersive region 332.

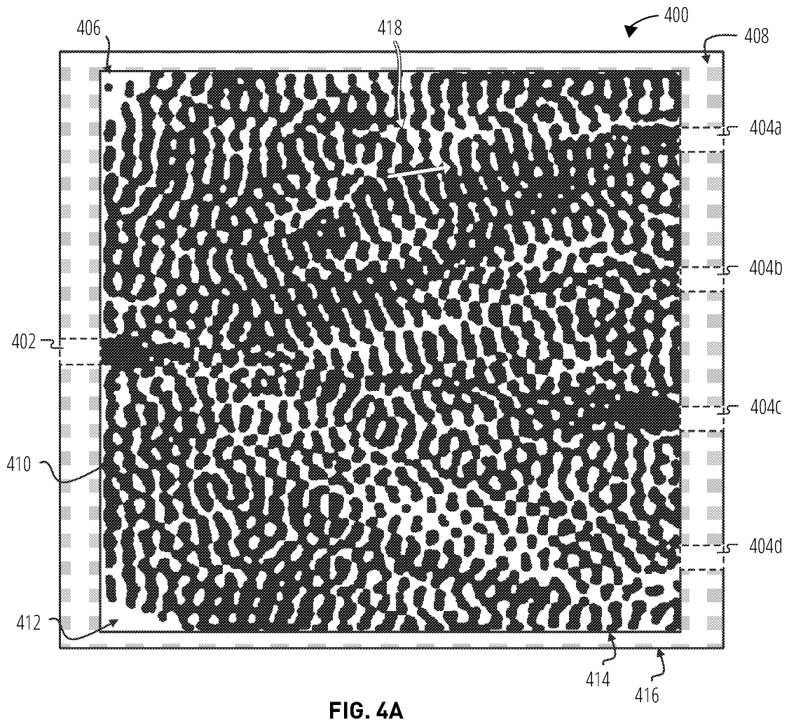

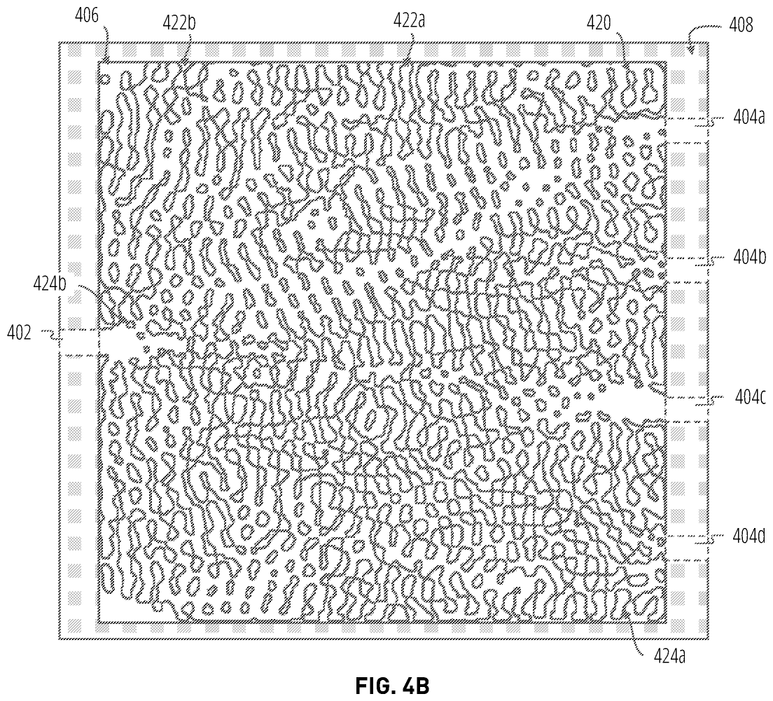

As illustrated in FIG. 3A, and more clearly shown in FIG. 3D and FIG. 4A-FIG. 4B, the shape and arrangement of the first and second material that are inhomogeneously interspersed create a plurality of interfaces that collectively form a material interface pattern along a cross-sectional area of dispersive region 332 that is at least partially surrounded by a periphery region 318 that includes the second material. In some embodiments periphery region 318 has a substantially homogeneous composition that includes the second material. In the illustrated embodiment, dispersive region 332 includes a first side 328 and a second side 330 that each interface with an inner boundary (i.e., the unlabeled dashed line of periphery region 318 disposed between dispersive region 332 and dashed-dotted line corresponding to an outer boundary of periphery region 318). First side 328 and second side 330 are disposed correspond to opposing sides of dispersive region 332. Input region 302 is disposed proximate to first side 328 (e.g., one side of input region 302 abuts first side 328 of dispersive region 332) while each of the plurality of output region 304 are disposed proximate to second side 330 (e.g., one side of each of the plurality of output region 304 abuts second side 330 of dispersive region 332).

In the illustrated embodiment each of the plurality of output regions 304 are parallel to each other one of the plurality of output region 304. However, in other embodiments the plurality of output regions 304 may not be parallel to one another or even disposed on the same side (e.g., one or more of the plurality of output regions 304 and/or input region 302 may be disposed proximate to sides of dispersive region 332 that are adjacent to first side 328 and/or second side 330). In some embodiments adjacent ones of the plurality of output regions are separated from each other by a common separation distance when the plurality of output regions includes at least three output regions. For example, as illustrated adjacent output region 308 and output region 310 are separated from one another by distance 306, which may be common to the separation distance between other pairs of adjacent output regions.

As illustrated in the embodiment of FIG. 3A, demultiplexer 316 includes four output regions 304 (e.g., output region 308, output region 310, output region 312, output region 314) that are each respectively mapped (i.e., by virtue of the structure of dispersive region 332) to a respective one of four channels included in a plurality of distinct wavelength channels. More specifically, the plurality of interfaces of dispersive region 332, defined by the inhomogeneous interspersion of a first material and a second material, form a material interface pattern along a cross-sectional area of the dispersive region 332 (e.g., as illustrated in FIG. 3A, FIG. 4A, or FIG. 4B) to cause the dispersive region 332 to optically separate each of the four channels from the multi-channel optical signal and route each of the four channels to a respective one of the four output regions 304 when the input region 302 regions the multi-channel optical signal.

It is noted that the first material and second material of dispersive region 332 are arranged and shaped within the dispersive region such that the material interface pattern is substantially proportional to a design obtainable with an inverse design process, which will be discussed in greater detail later in the present disclosure. More specifically, in some embodiments, the inverse design process may include iterative gradient-based optimization of a design based at least in part on a loss function that incorporates a performance loss (e.g., to enforce functionality) and a fabrication loss (e.g., to enforce fabricability and binarization of a first material and a second material) that is reduced or otherwise adjusted via iterative gradient-based optimization to generate the design. In the same or other embodiments, other optimization techniques may be used instead of, or jointly with, gradient-based optimization. Advantageously, this allows for optimization of a near unlimited number of design parameters to achieve functionality and performance within a predetermined area that may not have been possible with conventional design techniques.

For example, in one embodiment dispersive region 332 is structured to optically separate each of the four channels from the multi-channel optical signal within a predetermined area of 35 μm×35 μm (e.g., as defined by width 324 and length 326 of dispersive region 332) when the input region 302 receives the multi-channel optical signal. In the same or another embodiment, the dispersive region is structured to accommodate a common bandwidth for each of the four channels, each of the four channels having different center wavelengths. In one embodiment the common bandwidth is approximately 13 nm wide and the different center wavelengths is selected from a group consisting of 1271 nm, 1291 nm, 1311 nm, 1331 nm, 1506 nm, 1514 nm, 1551 nm, and 1571 nm. In some embodiments, the entire structure of demultiplexer 316 (e.g., including input region 302, periphery region 318, dispersive region 332, and plurality of output regions 304) fits within a predetermined area (e.g., as defined by width 320 and length 322). In one embodiment the predetermined area is 35 μm×35 μm. It is appreciated that in other embodiments dispersive region 332 and/or demultiplexer 316 fits within other areas greater than or less than 35 μm×35 μm, which may result in changes to the structure of dispersive region 332 (e.g., the arrangement and shape of the first and second material) and/or other components of demultiplexer 316.

In the same or other embodiments the dispersive region is structured to have a power transmission of −2 dB or greater from the input region 302, through the dispersive region 332, and to the corresponding one of the plurality of output regions 304 for a given wavelength within one of the plurality of distinct wavelength channels. For example, if channel 1 of a multi-channel optical signal is mapped to output region 308, then when demultiplexer 316 receives the multi-channel optical signal at input region 302 the dispersive region 332 will optically separate channel 1 from the multi-channel optical signal and guide a portion of the multi-channel optical signal corresponding to channel 1 to output region 308 with a power transmission of −2 dB or greater. In the same or another embodiment, dispersive region 332 is structured such that an adverse power transmission (i.e., isolation) for the given wavelength from the input region to any of the plurality of output regions other than the corresponding one of the plurality of output regions is −30 dB or less, −22 dB or less, or otherwise. For example, if channel 1 of a multi-channel optical signal is mapped to output region 308, then the adverse power transmission from input region 302 to any other one of the plurality of output regions (e.g., output region 310, output region 312, output region 314) other than the corresponding one of the plurality of output regions (e.g., output region 308) is −30 dB or less, −22 dB or less, or otherwise. In some embodiments, a maximum power reflection from demultiplexer 316 of an input signal (e.g., a multi-channel optical signal) received at an input region (e.g., input region 302) is reflected back to the input region by dispersive region 332 or otherwise is −40 dB or less, −20 dB or less, −8 dB or less, or otherwise. It is appreciated that in other embodiments the power transmission, adverse power transmission, maximum power, or other performance characteristics may be different than the respective values discussed herein, but the structure of dispersive region 332 may change due to the intrinsic relationship between structure, functionality, and performance of demultiplexer 316.

FIG. 3B illustrates a vertical schematic or stack of various layers that are included in the illustrated embodiment of demultiplexer 316. However, it is appreciated that the illustrated embodiment is not exhaustive and that certain features or elements may be omitted to avoid obscuring certain aspects of the invention. In the illustrated embodiment, demultiplexer 316 includes substrate 334, dielectric layer 336, active layer 338 (e.g., as shown in the cross-sectional illustration of FIG. 3A), and a cladding layer 340. In some embodiments, demultiplexer 316 may be, in part or otherwise, a photonic integrated circuit or silicon photonic device that is compatible with conventional fabrication techniques (e.g., lithographic techniques such as photolithographic, electron-beam lithography and the like, sputtering, thermal evaporation, physical and chemical vapor deposition, and the like).

In one embodiment a silicon on insulator (SOI) wafer may be initially provided that includes a support substrate (e.g., a silicon substrate) that corresponds to substrate 334, a silicon dioxide dielectric layer that corresponds to dielectric layer 336, a silicon layer (e.g., intrinsic, doped, or otherwise), and a oxide layer (e.g., intrinsic, grown, or otherwise). In one embodiment, the silicon in the active layer 338 may be etched selectively by lithographically creating a pattern on the SOI wafer that is transferred to SOI wafer via a dry etch process (e.g., via a photoresist mask or other hard mask) to remove portions of the silicon. The silicon may be etched all the way down to dielectric layer 336 to form voids that may subsequently be backfilled with silicon dioxide that is subsequently encapsulated with silicon dioxide to form cladding layer 340. In one embodiment, there may be several etch depths including a full etch depth of the silicon to obtain the targeted structure. In one embodiment, the silicon may be 206 nm thick and thus the full etch depth may be 206 nm. In some embodiments, this may be a two-step encapsulation process in which two silicon dioxide depositions are performed with an intermediate chemical mechanical planarization used to yield a planar surface.

FIG. 3C illustrates a more detailed view of active layer 338 (relative to FIG. 3B) taken along a portion of periphery region 318 that includes input region 302 of FIG. 3A. In the illustrated embodiment, active layer 338 includes a first material 342 with a refractive index of ϵ₁ and a second material 344 with a refractive index of ϵ₂ that is different from ϵ₁. Homogenous regions of the first material 342 and the second material 344 may form waveguides or portions of waveguides that correspond to input region 302 and plurality of output region 304 as illustrated in FIG. 3A and FIG. 3C.

FIG. 3D illustrates a more detailed view of active layer 338 (relative to FIG. 3B) taken along dispersive region 332. As described previously, active layer 338 includes a first material 342 (e.g., silicon) and a second material 344 (e.g., silicon dioxide) that are inhomogeneously interspersed to form a plurality of interfaces 346 that collectively form a material interface pattern. Each of the plurality of interfaces 346 that form the interface pattern correspond to a change in refractive index of dispersive region 332 to structure the dispersive region (i.e., the shape and arrangement of first material 342 and second material 344) to provide, at least in part, the functionality of demultiplexer 316 (i.e., optical separation of the plurality of distinct wavelength channels from the multi-channel optical signal and respective guidance of each of the plurality of distinct wavelength channels to the corresponding one of the plurality of output regions 304 when the input region 302 receives the multi-channel optical signal).

It is appreciated that in the illustrated embodiments of demultiplexer 316 as shown in FIG. 3A-FIG. 3D, the change in refractive index is shown as being vertically consistent (i.e., the first material 342 and second material 344 form interfaces that are substantially vertical or perpendicular to a lateral plane or cross-section of demultiplexer 316. However, in the same or other embodiments, the plurality of interfaces (e.g., interfaces 346 illustrated in FIG. 3D) may not be substantially perpendicular with the lateral plane or cross-section of demultiplexer 316.

FIG. 4A illustrates a more detailed cross-sectional view of a dispersive region of example photonic demultiplexer 400, in accordance with an embodiment of the present disclosure. FIG. 4B illustrates a more detailed view of an interface pattern formed by the shape and arrangement of a first material 410 and a second material 412 for the dispersive region of the photonic demultiplexer 400 of FIG. 4A. Photonic demultiplexer 400 is one possible implementation of MUX/DEMUX 114 illustrated in FIG. 1, demultiplexer 206 illustrated in FIG. 2A, and demultiplexer 316 illustrated in FIG. 3A-FIG. 3D.

As illustrated in FIG. 4A and FIG. 4B, photonic demultiplexer 400 includes an input region 402, a plurality of output regions 404a-404d, and a dispersive region 406 optically disposed between input region 402 and plurality of output regions 404a-404d. Dispersive region 406 is surrounded, at least in part, by a peripheral region 408 that includes an inner boundary 414 and an outer boundary 416. It is appreciated that like named or labeled elements of photonic demultiplexer 400 may similarly correspond to like named or labeled elements of other demultiplexers described in embodiments of the present disclosure.

The first material 410 (i.e., black colored regions within dispersive region 406) and second material 412 (i.e., white colored regions within dispersive region 406) of photonic demultiplexer 400 are inhomogeneously interspersed to create a plurality of interfaces that collectively form material interface pattern 420 as illustrated in FIG. 4B. More specifically, an inverse design process that utilizes iterative gradient-based optimization, Markov Chain Monte Carlo optimization, or other optimization techniques combined with first principles simulations to generate a design that is substantially replicated by dispersive region 406 within a proportional or scaled manner such that photonic demultiplexer 400 provides the desired functionality. In the illustrated embodiment, dispersive region 406 is structured to optically separate each of a plurality of distinct wavelength channels from a multi-channel optical signal and respectively guide each of the plurality of distinct wavelength channels to a corresponding one of the plurality of output regions 404a-404d when the input region 402 receives the multi-channel optical signal. More specifically, the plurality of output regions 404a-404d are respectively mapped to wavelength channels having center wavelengths correspond to 1271 nm, 1291 nm, 1311 nm, and 1331 nm. In another embodiment, output regions 404a-404d are respectfully mapped to wavelength channels having center wavelengths that correspond to 1506 nm, 1514 nm, 1551 nm, and 1571 nm.

As illustrated in FIG. 4B, material interface pattern 420, which is defined by the black lines within dispersive region 406 and corresponds to a change in refractive index within dispersive region 406, includes a plurality of protrusions 422a-422b. A first protrusion 422a is formed of the first material 410 and extends from peripheral region 408 into dispersive region 406. Similarly, a second protrusion 422b is formed of the second material 412 and extends from peripheral region 408 into dispersive region 406. Further illustrated in FIG. 4B, dispersive region 406 includes a plurality of islands 424a-424b formed of either the first material 410 or the second material 412. The plurality of islands 424a-424b include a first island 424a that is formed of the first material 410 and is surrounded by the second material 412. The plurality of islands 424a-424b also includes a second island 424b that is formed of the second material 412 and is surrounded by the first material 410.

In some embodiments, material interface pattern 420 includes one or more dendritic shapes, wherein each of the one or more dendritic shapes are defined as a branched structure formed from first material 410 or second material 412 and having a width that alternates between increasing and decreasing in size along a corresponding direction. Referring back to FIG. 4A, for clarity, dendritic structure 418 is labeled with a white arrow having a black border. As can be seen, the width of dendritic structure 418 alternatively increases and decreases in size along a corresponding direction (i.e., the white labeled arrow overlaying a length of dendritic structure 418) to create a branched structure. It is appreciated that in other embodiments there may be no protrusions, there may be no islands, there may be no dendritic structures, or there may be any number, including zero, of protrusions, islands of any material included in the dispersive region 406, dendritic structures, or a combination thereof.

In some embodiments, the inverse design process includes a fabrication loss that enforces a minimum feature size, for example, to ensure fabricability of the design. In the illustrated embodiment of photonic demultiplexer 400 illustrated in FIG. 4A and FIG. 4B, material interface pattern 420 is shaped to enforce a minimum feature size within dispersive region 406 such that the plurality of interfaces within the cross-sectional area formed with first material 410 and second material 412 do not have a radius of curvature with a magnitude of less than a threshold size. For example, if the minimum feature size is 150 nm, the radius of curvature for any of the plurality of interfaces have a magnitude of less than the threshold size, which corresponds the inverse of half the minimum feature size (i.e., 1/75 nm⁻¹). Enforcement of such a minimum feature size prevents the inverse design process from generating designs that are not fabricable by considering manufacturing constraints, limitations, and/or yield. In the same or other embodiments, different or additional checks on metrics related to fabricability may be utilized to enforce a minimum width or spacing as a minimum feature size.

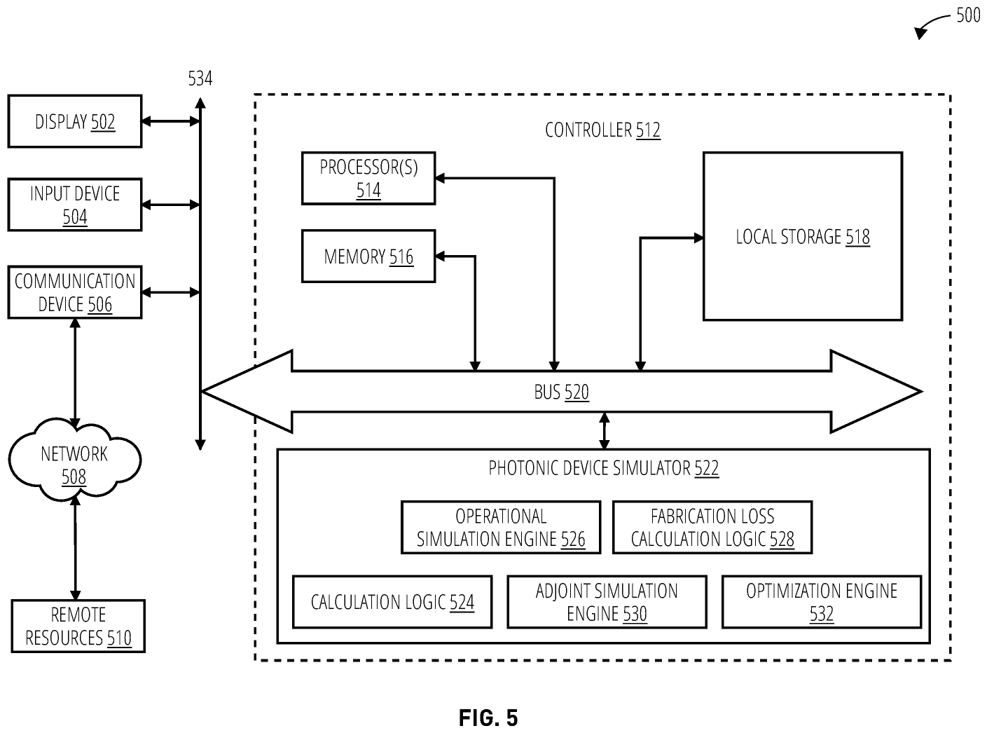

FIG. 5 is a functional block diagram illustrating a system 500 for generating a design of a photonic integrated circuit (i.e., photonic device), in accordance with an embodiment of the disclosure. System 500 may be utilized to perform an inverse design process that generates a design with iterative gradient-based optimization that takes into consideration the underlying physics that govern the operation of the photonic integrated circuit. More specifically, system 500 is a design tool that may be utilized to optimize structural parameters (e.g., shape and arrangement of a first material and a second material within the dispersive region of the embodiments described in the present disclosure) of photonic integrated circuits based on first-principles simulations (e.g., electromagnetic simulations to determine a field response of the photonic device to an excitation source) and iterative gradient-based optimization. In other words, system 500 may provide a design obtained via the inverse design process that is substantially replicated (i.e., proportionally scaled) by dispersive region 332 and dispersive region 406 of demultiplexer 316 and photonic demultiplexer 400 illustrated in FIG. 3A and FIG. 4A, respectively.

As illustrated, system 500 includes controller 512, display 502, input device(s) 504, communication device(s) 506, network 508, remote resources 510, bus 534, and bus 520. Controller 512 includes processor 514, memory 516, local storage 518, and photonic device simulator 522. Photonic device simulator 522 includes operational simulation engine 526, fabrication loss calculation logic 528, calculation logic 524, adjoint simulation engine 530, and optimization engine 532. It is appreciated that in some embodiments, controller 512 may be a distributed system.

Controller 512 is coupled to display 502 (e.g., a light emitting diode display, a liquid crystal display, and the like) coupled to bus 534 through bus 520 for displaying information to a user utilizing system 500 to optimize structural parameters of the photonic device (i.e., demultiplexer). Input device 504 is coupled to bus 534 through bus 520 for communicating information and command selections to processor 514. Input device 504 may include a mouse, trackball, keyboard, stylus, or other computer peripheral, to facilitate an interaction between the user and controller 512. In response, controller 512 may provide verification of the interaction through display 502.

Another device, which may optionally be coupled to controller 512, is one or more communication device(s) 506 for accessing remote resources 510 of a distributed system via network 508. Communication device 506 may include any of a number of networking peripheral devices such as those used for coupling to an Ethernet, Internet, or wide area network, and the like. Communication device 506 may further include a mechanism that provides connectivity between controller 512 and the outside world. Note that any or all of the components of system 500 illustrated in FIG. 5 and associated hardware may be used in various embodiments of the present disclosure. The remote resources 510 may be part of a distributed system and include any number of processors, memory, and other resources for optimizing the structural parameters of the photonic device.

Controller 512 orchestrates operation of system 500 for optimizing structural parameters of the photonic device. Processor 514 (e.g., one or more central processing units, graphics processing units, and/or tensor processing units, etc.), memory 516 (e.g., volatile memory such as DRAM and SRAM, non-volatile memory such as ROM, flash memory, and the like), local storage 518 (e.g., magnetic memory such as computer disk drives), and the photonic device simulator 522 are coupled to each other through bus 520. Controller 512 includes software (e.g., instructions included in memory 516 coupled to processor 514) and/or hardware logic (e.g., application specific integrated circuits, field-programmable gate arrays, and the like) that when executed by controller 512 causes controller 512 or system 500 to perform operations. The operations may be based on instructions stored within any one of, or a combination of, memory 516, local storage 518, physical device simulator 522, and remote resources 510 accessed through network 508.

In the illustrated embodiment, the components of photonic device simulator 522 are utilized to optimize structural parameters of the photonic device (e.g., MUX/DEMUX 114 of FIG. 1, demultiplexer 206 of FIG. 2A, multiplexer 208 of FIG. 2B, demultiplexer 316 of FIG. 3A-FIG. 3D, and photonic demultiplexer 400 of FIG. 4A-FIG. 4B). In some embodiments, system 500 may optimize the structural parameters of the photonic device via, inter alia, simulations (e.g., operational and adjoint simulations) that utilize a finite-difference time-domain (FDTD) method, a finite-difference frequency-domain (FDFD) method, or any other suitable technique to model the field response (e.g., electric and magnetic fields within the photonic device). The operational simulation engine 526 provides instructions for performing an electromagnetic simulation of the photonic device operating in response to an excitation source within a virtual prototype. In particular, the operational simulation determines a field response of the virtual prototype (and thus the photonic device, which is described by the virtual prototype) in response to the excitation source for determining a performance metric of the physical device (e.g., based off an initial description or input design of the photonic device that describes the structural parameters of the photonic device within the virtual prototype with a plurality of voxels). The structural parameters may correspond, for example, to the specific design, material compositions, dimensions, and the like of the physical device. Fabrication loss calculation logic 528 provides instructions for determining a fabrication loss, which is utilized to enforce a minimum feature size to ensure fabricability. In some embodiments, the fabrication loss is also used to enforce binarization of the design (i.e., such that the photonic device includes a first material and a second material that are interspersed to form a plurality of interfaces). Calculation logic 524 computes a loss metric determined via a loss function that incorporates a performance loss, based on the performance metric, and the fabrication loss. Adjoint simulation engine 530 is utilized in conjunction with the operational simulation engine 526 to perform an adjoint simulation of the photonic device to backpropagate the loss metric through the virtual prototype via the loss function to determine how changes in the structural parameters of the photonic device influence the loss metric (i.e., the gradient of the loss function with respect to the structural parameters, otherwise known as a sensitivity map). Optimization engine 532 is utilized to update the structural parameters of the photonic device to reduce the loss metric and generate a revised description (i.e., revising the design) of the photonic device.

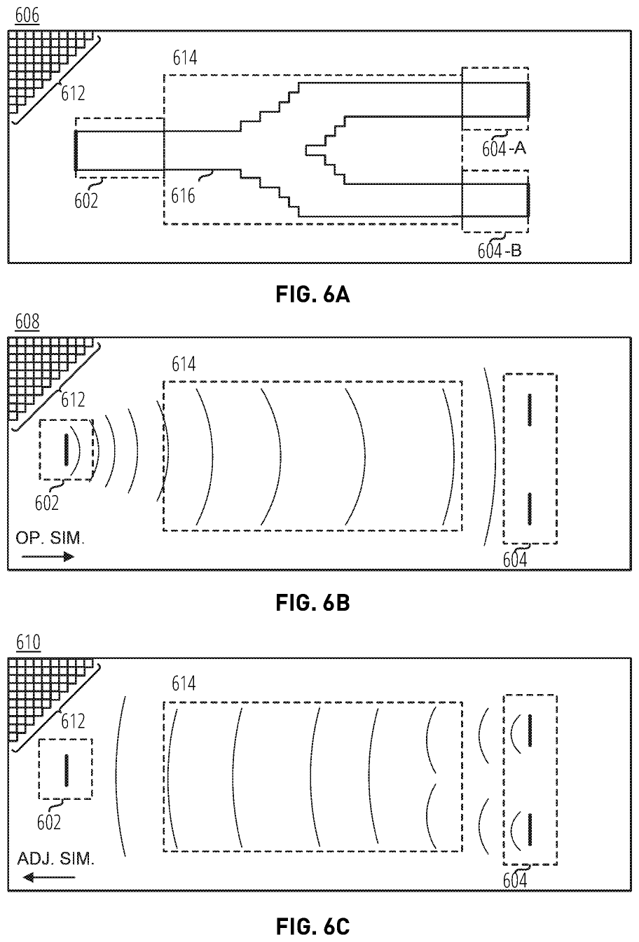

FIG. 6A-FIG. 6C respectively illustrate non-limiting example embodiments of an initial set up of a virtual prototype 606 describing a photonic device, performing an operational simulation of the photonic device in response to an excitation source within the virtual prototype 608, and performing an adjoint simulation of the photonic device within the virtual prototype 610 according to various aspects of the present disclosure. The initial set up of the virtual prototype, 1-dimensional representation of the virtual prototype, operational simulation of the physical device, and adjoint simulation of the physical device may be implemented with system 500 illustrated in FIG. 5.

As illustrated in FIG. 6A-FIG. 6C, the virtual prototype is represented in two dimensions. However, it is appreciated that other dimensionality (e.g., 3-dimensional space) may also be used to describe the virtual prototype and the photonic device. In some embodiments, optimization of structural parameters of the photonic device illustrated in FIG. 6A-FIG. 6C may be achieved via an inverse design process including, inter alia, simulations (e.g., operational simulations and adjoint simulations) that utilize a finite-difference time-domain (FDTD) method, a finite-difference frequency-domain (FDFD) method, or any other suitable technique to model the field response (e.g., electric and magnetic field) to an excitation source.

FIG. 6A illustrates a demonstrative virtual prototype 606 describing a photonic integrated circuit (i.e., a photonic device such as a waveguide, demultiplexer, and the like), in accordance with a non-limiting example embodiment of the present disclosure. More specifically, in response to receiving an initial description of a photonic device defined by one or more structural parameters (e.g., an input design), a system (e.g., system 500 of FIG. 5) configures a virtual prototype 606 to be representative of the photonic device. As illustrated, the virtual prototype 606 (and subsequently the photonic device) is described by a plurality of voxels 612, which represent individual elements (i.e., discretized) of the two-dimensional (or other dimensionality) space. Each of the voxels 612 is illustrated as a two-dimensional square; however, it is appreciated that the voxel may be represented as cubes or other shapes in three-dimensional space. It is appreciated that the specific shape and dimensionality of the plurality of voxels 612 may be adjusted dependent on the virtual prototype 606 and photonic device being simulated. It is further noted that only a portion of the plurality of voxels 612 are illustrated to avoid obscuring other aspects of the virtual prototype 606.

Each of the plurality of voxels 612 may be associated with a structural value, a field value, and a source value. Collectively, the structural values of the virtual prototype 606 describe the structural parameters of the photonic device. In one embodiment, the structural values may correspond to a relative permittivity, permeability, and/or refractive index that collectively describe structural (i.e., material) boundaries or interfaces of the photonic device (e.g., material interface pattern 420 of FIG. 4B). For example, an interface 616 is representative of where relative permittivity changes within the virtual prototype 606 and may define a boundary of the photonic device where a first material meets or otherwise interfaces with a second material. The field value describes the field (or loss) response that is calculated (e.g., via Maxwell's equations) in response to an excitation source described by the source value. The field response, for example, may correspond to a vector describing the electric and/or magnetic fields (e.g., in one or more orthogonal directions) at a particular time step for each of the plurality of voxels 612. Thus, the field response may be based, at least in part, on the structural parameters of the photonic device and the excitation source.

In the illustrated embodiment, the photonic device corresponds to an optical demultiplexer having a design region 614 (e.g., corresponding to dispersive region 332 of FIG. 3A, and/or dispersive region 406 of FIG. 4A), in which structural parameters of the physical device may be updated or otherwise revised. More specifically, through an inverse design process, iterative gradient-based optimization of a loss metric determined from a loss function is performed to generate a design of the photonic device that functionally causes a multi-channel optical signal to be demultiplexed and guided from input port 602 to a corresponding one of the output ports 604. Thus, input port 602 (e.g., corresponding to input region 302 of FIG. 3A, input region 402 of FIG. 4A, and the like) of the photonic device corresponds to a location of an excitation source to provide an output (e.g., a Gaussian pulse, a wave, a waveguide mode response, and the like). The output of the excitation source interacts with the photonic device based on the structural parameters (e.g., an electromagnetic wave corresponding to the excitation source may be perturbed, retransmitted, attenuated, refracted, reflected, diffracted, scattered, absorbed, dispersed, amplified, or otherwise as the wave propagates through the photonic device within virtual prototype 606). In other words, the excitation source may cause the field response of the photonic device to change, which is dependent on the underlying physics governing the physical domain and the structural parameters of the photonic device. The excitation source originates or is otherwise proximate to input port 602 and is positioned to propagate (or otherwise influence the field value of the plurality of voxel) through the design region 614 towards output ports 604 of the photonic device. In the illustrated embodiment, the input port 602 and output ports 604 are positioned outside of the design region 614. In other words, in the illustrated embodiment, only a portion of the structural parameters of the photonic device is optimizable.

However, in other embodiments, the entirety of the photonic device may be placed within the design region 614 such that the structural parameters may represent any portion or the entirety of the design of the photonic device. The electric and magnetic fields within the virtual prototype 606 (and subsequently the photonic device) may change (e.g., represented by the field value of the individual voxel that collectively correspond to the field response of the virtual prototype) in response to the excitation source. The output ports 604 of the optical demultiplexer may be used for determining a performance metric of the photonic device in response to the excitation source (e.g., power transmission from input port 602 to a specific one of the output ports 604). The initial description of the photonic device, including initial structural parameters, excitation sources, performance parameters or metrics, and other parameters describing the photonic device, are received by the system (e.g., system 500 of FIG. 5) and used to configure the virtual prototype 606 for performing a first-principles based simulation of the photonic device. These specific values and parameters may be defined directly by a user (e.g., of system 500 in FIG. 5), indirectly (e.g., via controller 512 culling pre-determined values stored in memory 516, local storage 518, or remote resources 510), or a combination thereof.

FIG. 6B illustrates a non-limiting example embodiment of an operational simulation of the photonic device in response to an excitation source within the virtual prototype 608, in accordance with various aspects of the present disclosure. In the illustrated embodiment, the photonic device is an optical demultiplexer structured to optically separate each of a plurality of distinct wavelength channels included in a multi-channel optical signal received at input port 602 and respectively guide each of the plurality of distinct wavelength channels to a corresponding one of the plurality of output ports 604. The excitation source may be selected (randomly or otherwise) from the plurality of distinct wavelength channels and originates at input port 602 having a specified spatial, phase, and/or temporal profile. The operational simulation occurs over a plurality of time steps, including the illustrated time step. When performing the operational simulation, changes to the field response (e.g., the field value) for each of the plurality of voxels 612 are incrementally updated in response to the excitation source over the plurality of time steps. The changes in the field response at a particular time step are based, at least in part, on the structural parameters, the excitation source, and the field response of the virtual prototype 610 at the immediately prior time step included in the plurality of time steps. Similarly, in some embodiments the source value of the plurality of voxels 612 is updated (e.g., based on the spatial profile and/or temporal profile describing the excitation source). It is appreciated that the operational simulation is incremental and that the field values (and source values) of the virtual prototype 610 are updated incrementally at each time step as time moves forward for each of the plurality of time steps during the operational simulation. It is further noted that in some embodiments, the update is an iterative process and that the update of each field and source value is based, at least in part, on the previous update of each field and source value.

Once the operational simulation reaches a steady state (e.g., changes to the field values in response to the excitation source substantially stabilize or reduce to negligible values) or otherwise concludes, one or more performance metrics may be determined. In one embodiment, the performance metric corresponds to the power transmission at a corresponding one of the output ports 604 mapped to the distinct wavelength channel being simulated by the excitation source. In other words, in some embodiments, the performance metric represents power (at one or more frequencies of interest) in the target mode shape at the specific locations of the output ports 604. A loss value or metric of the input design (e.g., the initial design and/or any refined design in which the structural parameters have been updated) based, at least in part, on the performance metric may be determined via a loss function. The loss metric, in conjunction with an adjoint simulation, may be utilized to determine a structural gradient (e.g., influence of structural parameters on loss metric) for updating or otherwise revising the structural parameters to reduce the loss metric (i.e. increase the performance metric). It is noted that the loss metric may be further based on a fabrication loss value that is utilized to enforce a minimum feature size of the photonic device to promote fabricability of the device, and/or other loss values.

FIG. 6C illustrates a non-limiting example embodiment of an adjoint simulation within the virtual prototype 610 by backpropagating a loss metric, in accordance with various aspects of the present disclosure. More specifically, the adjoint simulation is a time-backwards simulation in which a loss metric is treated as an excitation source that interacts with the photonic device and causes a loss response. In other words, an adjoint (or virtual source) based on the loss metric is placed at the output region (e.g., output ports 604) or other location that corresponds to a location used when determining the performance metric. The adjoint source(s) is then treated as a physical stimuli or an excitation source during the adjoint simulation. A loss response of the virtual prototype 608 is computed for each of the plurality of time steps (e.g., backwards in time) in response to the adjoint source. The loss response collectively refers to loss values of the plurality of voxels 612 that are incrementally updated in response to the adjoint source over the plurality of time steps. The change in loss response based on the loss metric may correspond to a loss gradient, which is indicative of how changes in the field response of the physical device influence the loss metric. The fields computed in response to the adjoint source are combined with the fields from the operational simulation to obtain a structural gradient of the photonic device/virtual prototype (e.g., how changes in the structural parameters of the photonic device within the virtual prototype influence the loss metric). Once the structural gradient of a particular cycle (e.g., operational and adjoint simulation) is known, the structural parameters may be updated to reduce the loss metric and generate a revised description or design of the photonic device.

In some embodiments, iterative cycles of performing the operational simulation, and adjoint simulation, determining the structural gradient, and updating the structural parameters to reduce the loss metric are performed successively as part of an inverse design process that utilizes iterative gradient-based optimization. An optimization scheme such as gradient descent may be utilized to determine specific amounts or degrees of changes to the structural parameters of the photonic device to incrementally reduce the loss metric. More specifically, after each cycle the structural parameters are updated (e.g., optimized) to reduce the loss metric. The operational simulation, adjoint simulation, and updating the structural parameters are iteratively repeated until the loss metric substantially converges or is otherwise below or within a threshold value or range such that the photonic device provides the desired performed while maintaining fabricability.

One problem in designing physical devices such as the photonic devices described above is that fabrication systems generally do not produce photonic devices that have the precise structure that is simulated using the techniques described above. The fabrication of photonic devices using fabrication systems such as semiconductor foundries involves a complex, multi-stage process of transferring the design from a photomask to a silicon wafer. Despite pre-corrections made to the photomask to compensate for distortion effects introduced by the photolithography process, the fabricated physical device still may exhibit shape distortions including but not limited to rounding of sharp corners, erosion or dilation of shape contours, oblique sidewall angles, and non-uniform layer thicknesses. These distortions are due to statistical variations of semiconductor processing and can affect performance of the manufactured physical devices in unexpected ways, given the delicate wave-interference physics which underlies the performance of physical devices such as the photonic devices described herein.

In order to compensate for these changes in a design for a physical device that are introduced by a fabrication process, a fabrication model that represents the changes that occur during the fabrication process can be inserted into an inverse design process so that the simulation of the physical device more accurately represents the output of the fabrication process.

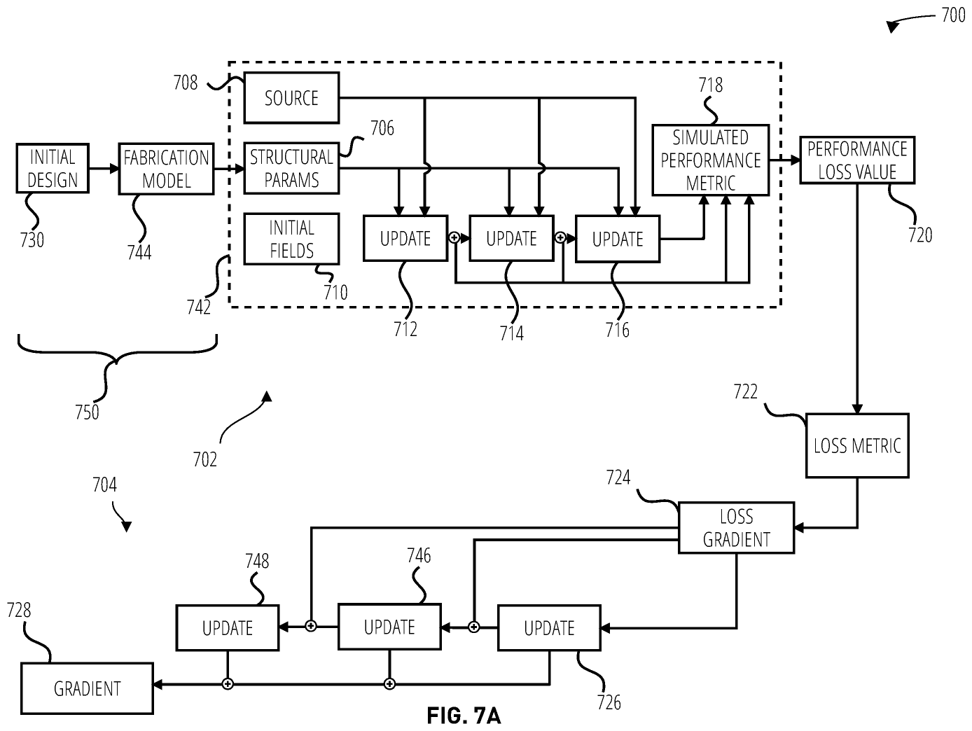

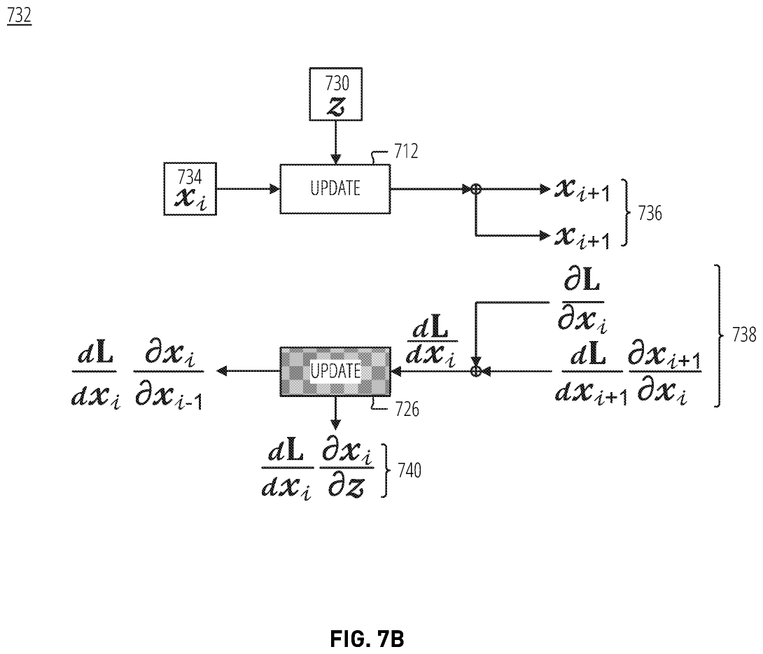

FIG. 7A is a flow chart 700 illustrating example time steps for an operational simulation 702 and an adjoint simulation 704 for such an inverse design process that uses a fabrication model to predict the output of the fabrication system based on an intended design such that the simulation may more accurately represent the real-world performance of the physical device fabricated based on the intended design, in accordance with various aspects of the present disclosure. Flow chart 700 is one possible implementation that a system may use to perform the operational simulation 702 and adjoint simulation 704 of the virtual prototype describing a photonic integrated circuit (e.g., an optical device operating in an electromagnetic domain such as a photonic demultiplexer). In the illustrated embodiment, the operational simulation 702 utilizes a technique such as a finite-difference time-domain (FDTD) method, a finite-difference frequency-domain (FDFD) method, or another method to model the field response (both electric and magnetic) or loss response at each of a plurality of voxels for a plurality of time steps in response to physical stimuli corresponding to an excitation source and/or adjoint source.

As illustrated in FIG. 7A, the operational simulation 702 includes a configuration portion 750 and a simulation portion 742. In the configuration portion 750, an initial design 730 is received that includes structural parameters for a physical device such as a photonic device to be simulated. In some embodiments, the initial design 730 may also include additional or different information regarding the design, including but not limited to a linear function to define the structural parameters (instead of the structural parameters themselves), desired performance values, a performance loss function to be used to compare simulated performance to desired performance, or other information.

After receiving the initial design 730, the operational simulation 702 uses a fabrication model 744 to simulate the fabrication of the photonic device based on the initial structural parameters to create structural parameters 706 to be simulated in the simulation portion 742. In some embodiments, the fabrication model 744 is a sequence of differentiable operations that embodies differences from the initial design 730 that will be introduced by a fabrication system during fabrication. In some embodiments, instead of a sequence of differentiable operations, the fabrication model 744 may be represented by a neural network. An example architecture for the fabrication model 744 and parameters for the fabrication model 744 that may be learned using an optimization process as described in further detail below.

After the structural parameters 706 are determined using the fabrication model 744, the operational simulation 702 proceeds to a simulation portion 742. The simulation portion 742 occurs over a plurality of time-steps (e.g., from an initial time step to a final time step over a pre-determined or conditional number of time steps having a specified time step size) and models changes (e.g., from the initial field value 710) in electric and magnetic fields of a plurality of voxels describing the virtual prototype and/or photonic device that collectively correspond to the field response. More specifically, update operations (e.g., update operation 712, update operation 714, and update operation 716) are iterative and based on the field response, structural parameters 706, and one or more excitation sources 708. Each update operation is succeeded by another update operation, which are representative of successive steps forward in time within the plurality of time steps. For example, update operation 714 updates the field values 734 (see, e.g., FIG. 7B) based on the field response determined from the previous update operation 712, excitation sources 708, and the structural parameters 706. Similarly, update operation 716 updates the field values 736 (see, e.g., FIG. 7B) based on the field response determined from update operation 714. In other words, at each time step of the operational simulation 702 the field values (and thus field response) are updated based on the previous field response and structural parameters of the photonic device.

Once the final time step of the simulation portion 742 is performed (although three update operations are illustrated for the sake of clarity and brevity, in some embodiments more than three update operations are performed), a simulated performance metric 718 is used to determine a performance loss value 720 associated with the structural parameters 706. In some embodiments, the simulated performance metric 718 is a characterization of the performance of the simulated device at one or more points (e.g., at the output ports of the device) and at one or more bandwidths, similar to the illustration in FIG. 2C, and the performance loss value 720 may include a comparison of the simulated performance metric 718 to a desired performance metric. The performance loss value 720 can then be used to determine (or used as) a loss metric 722. In some embodiments, the performance loss value 720 or loss metric 722 may include multiple values for multiple aspects of performance (e.g., for separate output ports).

From the loss metric 722, a loss gradient 724 may be determined. The loss gradient 724 may be treated as adjoint or virtual sources (e.g., physical stimuli or excitation source originating at an output region or port) which are backpropagated in reverse (from the final time step incrementally through the plurality of time steps until reaching the initial time step via update operation 726, update operation 746, and update operation 748) to determine gradient 728. Because it is determined based on the simulated performance metric 718, the gradient 728 is associated with the initial design 730 as modified by the fabrication model 744.

In the illustrated embodiment, the FDTD solve (e.g., simulation portion 742 of the operational simulation 702) and backward solve (e.g., adjoint simulation 704) problem are described pictorially, from a high-level, using only “update” and “loss” operations as well as their corresponding gradient operations. The simulation is set up initially in which the structural parameters, physical stimuli (i.e., excitation sources), and initial field states of the virtual prototype (and photonic device) are provided (e.g., via an initial description and/or input design). As discussed previously, the field values are updated in response to the excitation sources based on the structural parameters. More specifically, the update operation is given by φ, where [symbol] +φ [symbol] [symbol] [symbol] ) for [symbol] =1, . . . [symbol] . Here, [symbol] corresponds to the total number of time steps (e.g., the plurality of time steps) for the operational simulation, where [symbol] corresponds to the field response (the field value associated with the electric and magnetic fields of each of the plurality of voxels) of the virtual prototype at time step [symbol] , [symbol] , corresponds to the excitation source(s) (the source value associated with the electric and magnetic fields for each of the plurality of voxels) of the virtual prototype at time step [symbol] , and [symbol] corresponds to the structural parameters describing the topology and/or material properties of the physical device (e.g., relative permittivity, index of refraction, and the like).

It is noted that using the FDTD method, the update operation may specifically be stated as:

φ( [symbol] , [symbol] , [symbol] )=A( [symbol] ) [symbol] +B( [symbol] )

[symbol]

That is to say the FDTD update is linear with respect to the field and source terms. Concretely, A( [symbol] ) ∈ [symbol] ^{N×N} and B( [symbol] )∈ [symbol] ^{N×N} are linear operators which depend on the structural parameters, [symbol] , and act on the fields, [symbol] , and the sources, [symbol] , respectively. Here, it is assumed that [symbol] , [symbol] ∈ [symbol] ^{N} where N is the number of FDTD field components in the operational simulation. Additionally, the loss operation (e.g., loss function) may be given by L=ƒ( [symbol] , . . . , [symbol] ), which takes as input the computed fields and produces a single, real-valued scalar (e.g., the loss metric) that can be reduced and/or minimized.

In terms of revising or otherwise optimizing the structural parameters of the physical device, the relevant quantity to produce is dL/dz, which is used to describe the influence of changes in the structural parameters of the initial design 730 on the loss value and is denoted as the gradient 728 illustrated in FIG. 7A.

FIG. 7B is a chart 732 illustrating the relationship between the update operation for the operational simulation and the adjoint simulation (e.g., backpropagation), in accordance with an embodiment of the present disclosure. More specifically, FIG. 7B summarizes the operational and adjoint simulation relationships that are involved in computing the structural gradient, dL/dz, which include

$$\frac{\partial L}{\partial {x}_{i}} ,$$

$$\frac{\partial {x}_{i + 1}}{\partial {x}_{i}} ,$$

$$\frac{d L}{d {x}_{i}} ,$$

$$and \frac{\partial {x}_{i}}{\partial z} .$$

The update operation 714 of the operational simulation 702 updates the field value 734, [symbol] , of the plurality of voxels at the [symbol] th time step to the next time step (i.e., [symbol] +1 time step), which correspond to the field values 736, [symbol] . The gradient 738 are utilized to determine for the backpropagation (e.g., update operation 726 backwards in time), which combined with the gradient 740 are used, at least in part, to calculate the L structural gradient, dL/d [symbol] . ∂L/∂ [symbol] is the contribution of each field to the loss metric, L. It is noted that this is the partial derivative, and therefore does not take into account the causal relationship of [symbol] → [symbol] . Thus,

$$\frac{\partial {x}_{i + 1}}{\partial {x}_{i}}$$

is utilized which encompasses the [symbol] → [symbol] relationship. The loss gradient, dL/d [symbol] , may also be used to compute the structural gradient, dL/d [symbol] , and corresponds to the total derivative of the field with respect to loss value, L. The loss gradient, dL/d [symbol] , at a particular time step, [symbol] , is equal to the summation of

$$\frac{\partial L}{\partial {x}_{i}} + \frac{d L}{d {x}_{i + 1}} \frac{\partial {x}_{i + 1}}{\partial {x}_{i}} .$$

Finally, ∂ [symbol] /∂ [symbol] , which corresponds to the field gradient, is used which is the contribution to dL/d [symbol] from each time/update step.

In particular, the memory footprint to directly compute ∂L/∂ [symbol] and dL/d [symbol] may be so large that it is difficult to store more than a handful of state Tensors. The state Tensor corresponds to storing the values of all of the FDTD cells (e.g., the plurality of voxels) for a single simulation time step. It is appreciated that the term “tensor” may refer to tensors in a mathematical sense or as described by the TensorFlow framework developed by Alphabet, Inc. In some embodiments the term “tensor” refers to a mathematical tensor which corresponds to a multidimensional array that follows specific transformation laws. In some embodiments, the term “tensor” refers to TensorFlow tensors, in which a tensor is described as a generalization of vectors and matrices to potentially higher dimensions (e.g., n-dimensional arrays of base data types), and is not necessarily limited to specific transformation laws. For example, for the general loss function ƒ, it may be necessary to store the fields, [symbol] , for all time steps, [symbol] . This is because, for most choices of ƒ, the gradient will be a function of the arguments of ƒ. This difficulty is compounded by the fact that the values of for larger values of [symbol] are needed before the values for smaller [symbol] due to the incremental updates of the field response and/or through backpropagation of the loss metric, which may prevent the use of schemes that attempt to store only the values ∂L/∂ [symbol] , at an immediate time step.

An additional difficulty is further illustrated when computing the structural gradient, dL/d [symbol] , which is given by:

$$\frac{d L}{d z} = {\sum }_{i} \frac{d L}{d {x}_{i}} \frac{\partial {x}_{i}}{\partial z} .$$

For completeness, the full form of the first term in the sum, dL/d [symbol] , is expressed as:

$$\frac{d L}{d {x}_{i}} = \frac{\partial L}{\partial {x}_{i}} + \frac{d L}{d {x}_{i + 1}} \frac{\partial {x}_{i + 1}}{\partial {x}_{i}}$$

Based on the definition of ϕ as described by equation (1), it is noted that

$$\frac{\partial {x}_{i + 1}}{\partial {x}_{i}} = A ( z ) ,$$

which can be substituted in equation (3) to arrive at an adjoint update for backpropagation (e.g., the update operations such as update operation 726), which can be expressed as:

$$\frac{d L}{d {x}_{i}} = \frac{\partial L}{\partial {x}_{i}} + \frac{d L}{d {x}_{i + 1}} A ( z ) ,$$

or

$${∇}_{{x}_{i}} L = {A ( z )}^{T} {∇}_{{x}_{i + 1}} L + \frac{\partial {L}^{T}}{\partial {x}_{i}}$$

The adjoint update is the backpropagation of the loss gradient (e.g., from the loss metric) from later to earlier time steps and may be referred to as a backwards solve for dL/d [symbol] . More specifically, the loss gradient may initially be based upon the backpropagation of a loss metric determined from the operational simulation with the loss function. The second term in the sum of the structural gradient, dL/d [symbol] , corresponds to the field gradient and is denoted as:

$$\frac{\partial {x}_{i}}{\partial z} = \frac{d ϕ ( {x}_{i - 1} , , z )}{d z} = \frac{d A ( z )}{d z} {x}_{i - 1} + \frac{d B ( z )}{d z} ,$$

for the particular form of ϕ described by the first equation above. Thus, each term of the sum associated depends on both for [symbol] >= [symbol] and for [symbol] < [symbol] . Since the dependency chains of these two terms are in opposite directions, it is concluded that computing dL/d [symbol] in this way requires the storage of [symbol] values for all of [symbol] . In some embodiments, the need to store all field value may be mitigated by a reduced representation of the fields.

Returning to FIG. 7A, the operational simulation 702 and adjoint simulation 704 as described above are used to optimize the initial design 730 with respect to a loss metric 722 that would typically represent a desired performance of the physical device.

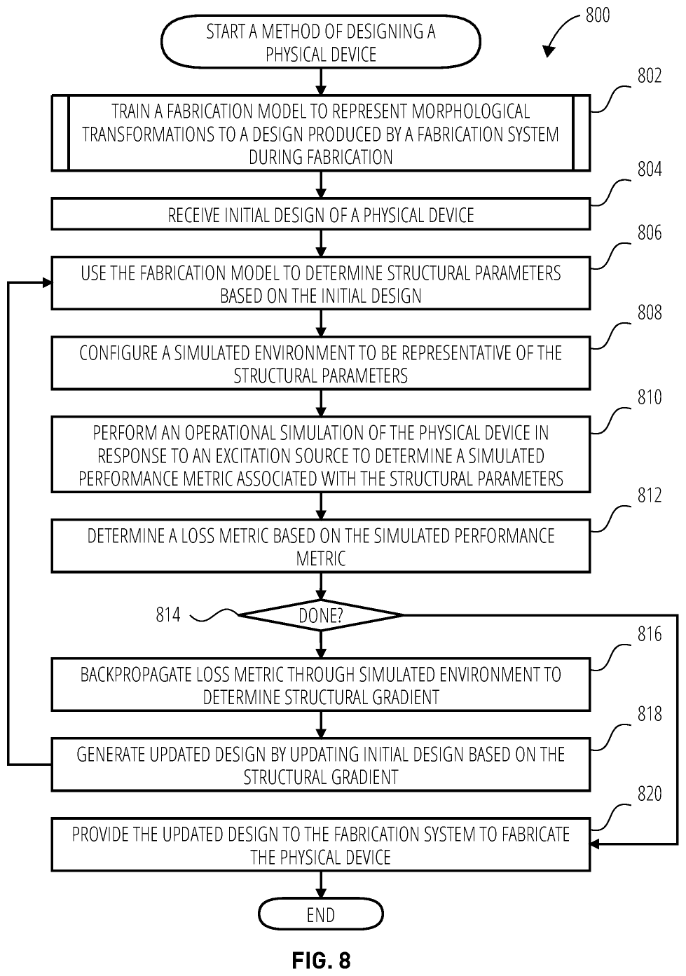

FIG. 8 is a flowchart that illustrates a non-limiting example embodiment

of a method of designing a physical device, in accordance with various aspects of the present disclosure. It is appreciated that method 800 uses an optimization process as illustrated in FIG. 7A and FIG. 7B that may be accomplished by performing operations with a system (e.g., design optimization system 500 of FIG. 5) to perform iterative gradient-based optimization. In the same or other embodiments, method 800 may be included as instructions and/or logic provided by at least one machine-accessible storage medium (e.g., non-transitory memory) that, when executed by one or more machines such as a computing device or a computing system, will cause the machine(s) to perform operations for generating and/or improving the design of the physical device/photonic integrated circuit. It is further appreciated that the order in which some or all of the process blocks appear in method 800 should not be deemed limiting. Rather, one of ordinary skill in the art having the benefit of the present disclosure will understand that some of the process blocks may be executed in a variety of orders not illustrated, or even in parallel.

From a start block, the method 800 proceeds to subroutine block 802

At block 804, an initial design of a physical device such as a photonic integrated circuit is received. In some embodiments, the initial design may describe structural parameters of the physical device within a simulated environment. The simulated environment may include a plurality of voxels that collectively describe the structural parameters of the physical device. Each of the plurality of voxels is associated with a structural value to describe the structural parameters, a field value to describe the field response (e.g., the electric and magnetic fields in one or more orthogonal directions) to physical stimuli (e.g., one or more excitation sources), and a source value to describe the physical stimuli. In some embodiments the initial design may be a first description of the physical device in which values for the structural parameters may be random values or null values outside of the periphery region such that there is no bias for the initial (e.g., first) design.

It is appreciated that the initial description or input design may be a relative term. Thus, in some embodiments an initial description may be a first description of the physical device described within the context of the simulated environment (e.g., a first input design for performing a first operational simulation). However, in other embodiments, the term initial description may refer to an initial description of a particular cycle (e.g., of performing an operational simulation, operating an adjoint simulation, and updating the structural parameters and/or locations of one or more ports). In such an embodiment, the initial design or design of that particular cycle may correspond to a revised description or refined design (e.g., generated from a previous cycle).

In some embodiments, the simulated environment includes a design region that includes a portion of the plurality of voxels which have structural parameters that may be updated, revised, or otherwise changed to optimize the structural parameters of the physical device. In the same or other embodiments, the structural parameters are associated with geometric boundaries and/or material compositions of the physical device based on the material properties (e.g., relative permittivity, index of refraction, etc.) of the simulated environment.

At block 806, the fabrication model 744 is used to determine structural parameters 706 based on the initial design. The fabrication model 744 is used to transform the structural parameters of the initial design into structural parameters that would be predicted to be generated using the fabrication process, and may use any suitable technique, including but not limited to performing one or more morphological operations as described below.

At block 808, a simulated environment is configured to be representative of the structural parameters 706. In some embodiments, the simulated environment is configured (e.g., the number of voxels, shape/arrangement of voxels, and specific values for the structural value, field value, and/or source value of the voxels are set based on the structural parameters 706).

In some embodiments the simulated environment includes a design region optically coupled between a first communication region and one or more second communication regions. In some embodiments, the first communication region may correspond to an input region or port (e.g., where an excitation source originates), while the second communication region may correspond to one or more output regions or ports (e.g., when designing a physical device where an output may be measured to determine the physical characteristics of the fabrication process). However, in other embodiments, the first communication region may correspond to an output region or port, while the plurality of second communication regions corresponds to a plurality of input ports or region.

Block 810 illustrates performing an operational simulation 702 of the physical device within the simulated environment operating in response to one or more excitation sources 708 to determine a simulated performance metric 718 associated with the structural parameters 706. More specifically, in some embodiments an electromagnetic simulation is performed in which a field response of the photonic integrated circuit is updated incrementally over a plurality of time steps to determine how the field response of the physical device changes due to the excitation sources 708. The field values of the plurality of voxels are updated in response to the excitation sources 708 and based, at least in part, on the structural parameters 706 of the integrated photonic circuit. Additionally, each update operation at a particular time step may also be based, at least in part, on a previous (e.g., immediately prior) time step.

Consequently, the operational simulation 702 simulates an interaction between the photonic device (i.e., the photonic integrated circuit) and a physical stimuli (i.e., one or more excitation sources) to determine a simulated output of the photonic device (e.g., at one or more of the output ports or regions) in response to the physical stimuli. The interaction may correspond to any one of, or combination of a perturbation, retransmission, attenuation, dispersion, refraction, reflection, diffraction, absorption, scattering, amplification, or otherwise of the physical stimuli within electromagnetic domain due, at least in part, to the structural parameters of the photonic device and underlying physics governing operation of the photonic device. Thus, the operational simulation simulates how the field response of the simulated environment changes due to the excitation source over a plurality of time steps (e.g., from an initial to final time step with a pre-determined step size).

For example, the excitation source may be light of one or more wavelengths specified by the initial design. The excitation source may originate at or be disposed proximate to the first communication region (i.e., a port designated as the input port) when performing the operational simulation. During the operational simulation, the field response at one or more output ports may then be utilized to determine a simulated performance metric 718 that represents a simulated power transmission of the photonic integrated circuit for the one or more wavelengths received by the input port.

At block 812, a loss metric 722 is determined based on the simulated performance metric 718. In some embodiments, a comparison of the simulated performance metric 718 to a desired performance metric may be used to determine a performance loss value 720, and the performance loss value 720 may be used to determine the loss metric 722. In some embodiments, the performance loss value 720 may be used directly as the loss metric 722. In some embodiments, the performance loss value 720 may be combined with measurements of other desired characteristics of the physical device to create the loss metric 722.

The method 800 then proceeds to a decision block 814, where a determination is made as to whether further iterations of the update of the initial design are to be processed. In some embodiments, the determination is based on whether the loss metric has converged to a global or local minimum value (i.e., the loss metric is not improving after two or more iterations of updating of the initial design). In some embodiments, the determination is based on whether the loss metric has reached a threshold value that indicates usable performance. In some embodiments, the determination is based on whether a predetermined number of update iterations have been performed.

If it is determined that further update iterations are desired, then the result of decision block 814 is NO, and the method 800 proceeds to block 816. Block 816 illustrates backpropagating the loss metric 722 through the simulated environment to determine a structural gradient. The loss metric is treated as an adjoint or virtual source and is backpropagated incrementally using a loss gradient 724 from a final time step to earlier time steps in a backwards simulation to determine the structural gradient 728 of the physical device.

Block 818 shows revising a design of the physical device (e.g., generated a revised description) by updating the initial design (e.g., structural parameters indicated by the initial design) based on the structural gradient 728. In some embodiments, adjusting for the loss metric may reduce the loss metric. However, in other embodiments, the loss metric may be adjusted or otherwise compensated in a manner that does not necessarily reduce the loss metric, In one embodiment, adjusting the loss metric may provide a general direction within the parameterization space to obtain designs that will ultimately result in increased performance while also maintaining device fabricability and targeted performance metrics. In some embodiments, the updated initial design is generated by utilizing an optimization scheme after a cycle of operational and adjoint simulations via a gradient descent algorithm, Markov Chain Monte Carlo algorithm, or other optimization techniques. After updating the initial design at block 818, the method 800 returns to block 806 to conduct a subsequent iteration of the optimization process and further improve the updated design.

Returning to decision block 814, if it is determined that further update iterations are not desired, then the result of decision block 814 is YES, and the method 800 proceeds to block 820. Block 820 shows providing the updated design of the physical device to the fabrication system 904 to fabricate the physical device. The fabrication system 904 then fabricates the physical device based on the optimized design.

The method 800 then proceeds to an end block and terminates.

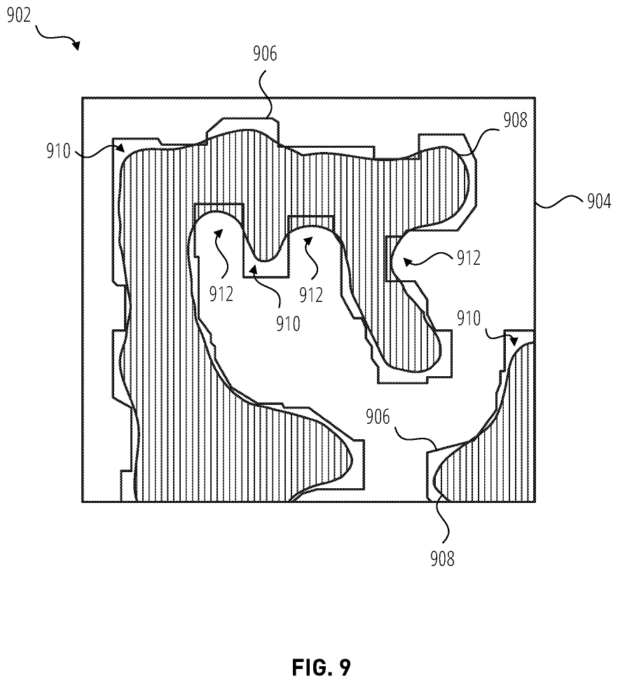

FIG. 9 is an illustration of a portion of a fabricated photonic device and its associated design that shows distortions introduced by the fabrication process. As shown, the design portion 902 includes a designed first material area 904 in which the design indicates that a first material should be present, and two designed second material areas 906 in which the design indicates that a second material should be present. If the design portion 902 were fabricated perfectly by the fabrication system, then the fabricated second material areas 908 (illustrated as vertically hashed areas in FIG. 9) would correspond exactly to the designed second material areas 906. However, the physical processes performed during the fabrication process introduce differences between the designed second material areas 906 and the fabricated second material areas 908.

It has been discovered that many of the distortions introduced by typical fabrication processes can be characterized as morphological operations. In the illustration, several areas that represent erosions 910 of the fabricated second material areas 908 (areas where the fabricated second material area does not extend as far as the designed second material area) and several areas that represent dilations 912 of the fabricated second material areas 908 (areas where the fabricated second material area extends farther than the designed second material area) are shown. Erosions and dilations are two types of morphological changes that are commonly introduced by fabrication processes, but should not be seen as limiting. In some embodiments, other morphological changes, such as morphological closings (a dilation followed by an erosion) and/or morphological openings (an erosion followed by a dilation) may be introduced by the fabrication system.

What is desired is a fabrication model that can be trained to efficiently represent distortions introduced by a fabrication process as a set of morphological operations.

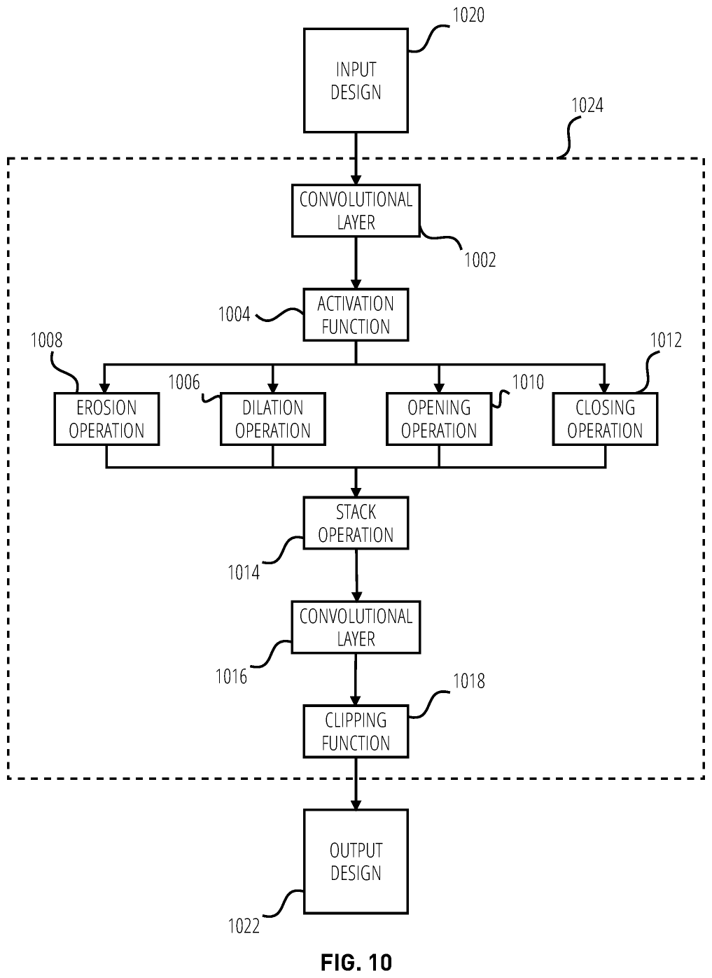

FIG. 10 is a schematic illustration of a non-limiting example embodiment of a fabrication model for simulating a fabrication process as a combination of morphological operations according to various aspects of the present disclosure. Overall, an input design 1020 (e.g., initial design 730) is provided to the fabrication model 1024 (e.g., fabrication model 744). The fabrication model 1024 simulates distortions that would be introduced by a given fabrication system when fabricating the input design 1020, and outputs the distorted design as output design 1022 (e.g., structural parameters 706).

As shown, the input of the fabrication model 1024 is first provided to a convolutional layer 1002, and then to an activation function 1004. One suitable activation function to be used as the activation function 1004 is a ReLU activation function, though any other suitable activation function may be used. In some embodiments, more than one convolutional layer 1002 may be stacked at convolutional layer 1002. A training process (discussed below) adjusts weights within the convolutional layer 1002 in order to find features that are likely to be affected by the morphological operations.

Once the feature set is obtained from the activation function 1004, one or more morphological operations are separately applied to the feature set. While fabrication models that attempt to directly model the distortions with convolutional layers alone have been attempted, it was found that training of convolutional layers alone were ineffective in learning the types of contours introduced by typical fabrication systems. By incorporating morphological operations into the fabrication model 1024, it is possible to train the model to learn the typical introduced distortions.

The illustrated fabrication model 1024 includes an erosion operation 1008, a dilation operation 1006, an opening operation 1010, and a closing operation 1012. Each of the morphological operations may be associated with one or more trainable filters. For example, an erosion operation 1008 may be defined as:

```
output [b, y, x, c] =
  min_{dy, dx} value [b,
      strides[1] * y − dilations[1] * dy,
      strides[2] * x − dilations[2] * dx,
      c] −
    filters[dy, dx, c]
```

wherein the value tensor and the output tensor have a shape [batch, in_height, in_width, depth]; and wherein the filters tensor has a shape [filters_height, filters_width, depth]. A dilation operation 1006 may be similar, but with a max operation replacing the min operation. For multi-step operations such as the opening operation 1010 and the closing operation 1012, separate filters may be provided for the incorporated dilation and erosion steps. The values in the filters tensor may be trained by a procedure such as procedure 1100 described below. In some embodiments, the other values, such as the strides and the dilations, may also be trained.

In some embodiments, more or fewer morphological operations may be included than those illustrated in FIG. 10. For example, in some embodiments, only an erosion operation 1008 and a dilation operation 1006 may be performed. As another example, in some embodiments, only an erosion operation 1008 or a dilation operation 1006 may be performed. A stack operation 1014 is applied to combine the results of the separate morphological operations

After the stack operation 1014, a convolutional layer 1016 processes the stacked results, and a clipping function 1018 is used to generate the output design 1022. Weights in the convolutional layer 1016 are adjusted during the training process discussed below in order to apply the results of the various types of morphological operations to appropriate features within the design (e.g., features that are likely to be eroded have the results of the erosion operation 1008 applied, features that are likely to be dilated have the results of the dilation operation 1006 applied, etc.). The clipping function 1018 ensures that the resulting values remain between in a range of valid values (e.g., in a range between 0 and 1, where 0 indicates presence of a background material such as an oxide and 1 indicates presence of a foreground material such as silicon at the corresponding location), and any suitable regularization, including but not limited to a pair of ReLU functions (e.g., ReLU(z)-ReLU(z−1)), may be used.

It should be noted that the fabrication model 1024 does not use a dense layer at the output. Accordingly, the fabrication model 1024 may be used on arbitrarily sized images. That is, the fabrication model 1024 may be trained using many small samples and then applied for inference to a larger sized design, whereas models that use a dense layer at the output would not be able to do so.

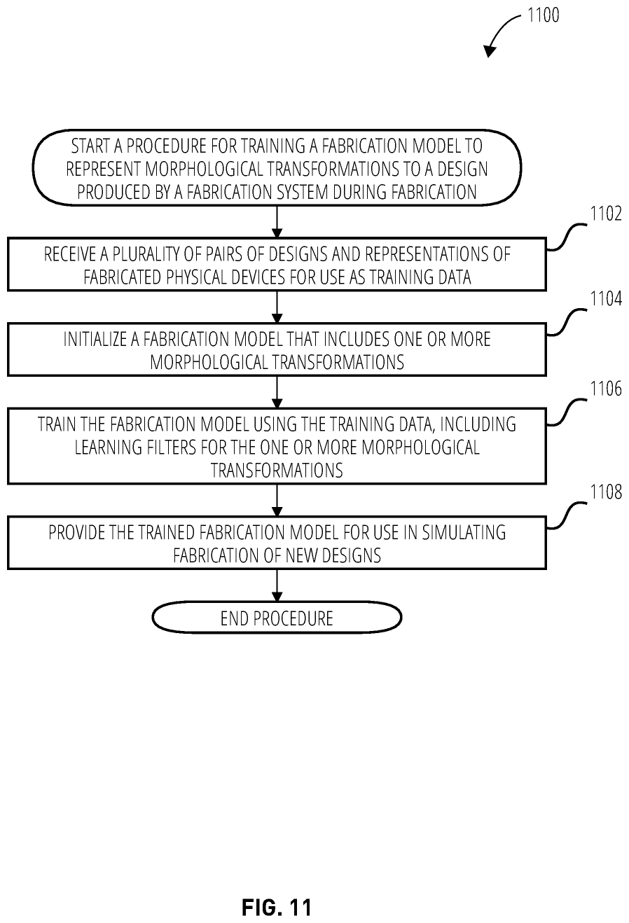

FIG. 11 is a flowchart that illustrates a non-limiting example embodiment of a procedure for training a fabrication model to represent morphological transformations to a design produced by a fabrication system during fabrication according to various aspects of the present disclosure. The procedure 1100 is a non-limiting example of a procedure suitable for use at subroutine block 802 in FIG. 8.

From a start block, the procedure 1100 advances to block 1102, where a plurality of pairs of designs and representations of fabricated physical devices for use as training data are received. Each pair of a design and a corresponding representation of a fabricated physical device is used as a piece of training data in the remainder of the procedure 1100. The representation of a fabricated physical device that corresponds to a given design may be obtained in any suitable format and in any suitable way.

In some embodiments, the design may be provided to the fabrication system to fabricate the physical device, and the fabricated physical device may be imaged using any suitable technique, including but not limited to scanning electron microscopy (SEM). The image, which may be binarized to be more easily compared to the corresponding design, may then be used as the representation of the fabricated physical device.

While obtaining SEM imagery of a fabricated physical device is possible, it is particularly time- and resource-intensive, and other techniques may allow for the creation of larger sets of training data. Accordingly, in some embodiments, a physical process simulator may be used to determine a representation of a fabricated physical device that corresponds to a design. The physical process simulator may be any suitable type of simulator that simulates the physical processes performed by the fabrication system, and may be provided by the provider of the fabrication system (e.g., a foundry) itself. While the physical process simulator is capable of generating an accurate representation of the fabricated physical device, the physical process simulator is typically too slow and/or resource intensive to use as the fabrication model 744 itself. The physical process simulator is also typically not differentiable, unlike the fabrication model 1024 illustrated in FIG. 10, which is differentiable. Hence, using the physical process simulator in an offline manner to generate training data for training the fabrication model 1024 (which is efficient enough to incorporate into the configuration portion 750 of the operational simulation 702 without unduly increasing its computing requirements, and which is differentiable) is preferable.

In some embodiments, other techniques may be used to predict the differences between the design and the fabricated physical device. For example, one may design physical devices that generate outputs that can be measured to indicate an amount of morphological transformation that was introduced by the fabrication system in fabricating the physical devices. Embodiments of techniques for determining such designs are disclosed in commonly owned, co-pending U.S. application Ser. No. 17/666399, filed Feb. 7, 2022, the entire disclosure of which is hereby incorporated by reference herein for all purposes. Accordingly, embodiments of the present disclosure may receive a plurality of such designs, receive measurements of performance metrics of physical devices as fabricated by the fabrication system based on the plurality of designs, and determine amounts of morphological transformations introduced by the fabrication system based on the measurements of the performance metrics. The morphological transformations may then be applied to the plurality of designs to generate predicted structures, and the predicted structures can be used as the representation of the fabricated physical device to train the fabrication model 1024.

Once the training data has been obtained, the procedure 1100 advances to block 1104, where a fabrication model that includes one or more morphological transformations (such as fabrication model 1024) is initialized. The fabrication model 1024 may be initialized using any suitable technique, including but not limited to setting weights in the fabrication model 1024 to random values, setting weights in the fabrication model 1024 to predetermined default values, and reusing weights from a previously trained fabrication model 1024.

At block 1106, the fabrication model is trained using the training data, including learning filters for the one or more morphological transformations. Any suitable technique may be used to train the fabrication model 1024, including but not limited to gradient descent and/or an Adam optimizer. The training process may adjust weights within the convolutional layers 1002, 1016 as well as learning the filters for the one or more morphological transformations.

At block 1108, the trained fabrication model 1024 is provided for use in simulating fabrication of new designs, such as described above with respect to FIG. 7A, FIG. 7B, and FIG. 8.

In the preceding description, numerous specific details are set forth to provide an understanding of various embodiments of the present disclosure. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The order in which some or all of the blocks appear in each method flowchart should not be deemed limiting. Rather, one of ordinary skill in the art having the benefit of the present disclosure will understand that actions associated with some of the blocks may be executed in a variety of orders not illustrated, or even in parallel.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A non-transitory computer-readable medium having computer-executable instructions stored thereon that, in response to execution by one or more processors of a computing system, cause the computing system to perform actions for optimizing a design for a physical device to be fabricated by a fabrication system; the actions comprising:
receiving, by the computing system, an initial design;
using, by the computing system, a fabrication model to determine structural parameters based on the initial design, wherein using the fabrication model includes applying one or more morphological transformations to the initial design that are predicted to be introduced by the fabrication system;
obtaining, by the computing system, a performance metric by simulating performance of the structural parameters;
determining, by the computing system, a loss metric based on the performance metric; and
backpropagating a gradient of the loss metric to generate an updated design.

2. The non-transitory computer-readable medium of claim 1, wherein the actions further comprise repeating the using, obtaining, determining, and backpropagating actions two or more times to generate a further updated design.

3. The non-transitory computer-readable medium of claim 1, wherein the morphological transformations include at least one of an erosion, a dilation, an opening, or a closing.

4. The non-transitory computer-readable medium of claim 1, wherein applying the one or more morphological transformations to the initial design that are predicted to be introduced by the fabrication system includes:
separately calculating at least two morphological transformations to the initial design;
stacking results of the at least two morphological transformations; and
applying a convolution to the stacked results to adjust relative effects of the at least two morphological transformations.

5. The non-transitory computer-readable medium of claim 1, wherein the actions further comprise training the fabrication model to predict the morphological transformations introduced by the fabrication system.

6. The non-transitory computer-readable medium of claim 5, wherein training the fabrication model includes:
receiving a plurality of designs;
receiving a plurality of images of structures of physical devices fabricated by the fabrication system using the plurality of designs; and
training the fabrication model using the plurality of designs and the plurality of images.

7. The non-transitory computer-readable medium of claim 5, wherein training the fabrication model includes:
receiving a plurality of designs;
generating a plurality of simulated structures based on the plurality of designs using a physical process simulator; and
training the fabrication model using the plurality of designs and the plurality of simulated structures.

8. The non-transitory computer-readable medium of claim 5, wherein training the fabrication model includes:
receiving a plurality of designs, wherein the plurality of designs are configured to generate physical devices having outputs that indicate morphological transformations introduced by the fabrication system;
receiving a plurality of performance metrics for physical devices fabricated by the fabrication system using the plurality of designs;
determining amounts of the morphological transformations introduced by the fabrication system based on the plurality of performance metrics;
generating a plurality of predicted structures based on the plurality of designs and the determined amounts of the morphological transformations; and
training the fabrication model using the plurality of designs and the plurality of predicted structures.

9. The non-transitory computer-readable medium of claim 1, wherein the fabrication system is configured to implement a photolithography process.

10. The non-transitory computer-readable medium of claim 1, wherein the physical device is a photonic device.

11. A computer-implemented method for optimizing a design for a physical device to be fabricated by a fabrication system; the method comprising:
receiving, by a computing system, an initial design;
using, by the computing system, a fabrication model to determine structural parameters based on the initial design, wherein using the fabrication model includes applying one or more morphological transformations to the initial design that are predicted to be introduced by the fabrication system;
obtaining, by the computing system, a performance metric by simulating performance of the structural parameters;
determining, by the computing system, a loss metric based on the performance metric; and
backpropagating a gradient of the loss metric to generate an updated design.

12. The computer-implemented method of claim 11, further comprising repeating the using, obtaining, determining, and backpropagating actions two or more times to generate a further updated design.

13. The computer-implemented method of claim 11, wherein the morphological transformations include at least one of an erosion, a dilation, an opening, or a closing.

14. The computer-implemented method of claim 11, wherein applying the one or more morphological transformations to the initial design that are predicted to be introduced by the fabrication system includes:
separately calculating at least two morphological transformations to the initial design;
stacking results of the at least two morphological transformations; and
applying a convolution to the stacked results to adjust relative effects of the at least two morphological transformations.

15. The computer-implemented method of claim 11, further comprising training the fabrication model to predict the morphological transformations introduced by the fabrication system.

16. The computer-implemented method of claim 15, wherein training the fabrication model includes:
receiving a plurality of designs;
receiving a plurality of images of structures of physical devices fabricated by the fabrication system using the plurality of designs; and
training the fabrication model using the plurality of designs and the plurality of images.

17. The computer-implemented method of claim 15, wherein training the fabrication model includes:
receiving a plurality of designs;
generating a plurality of simulated structures based on the plurality of designs using a physical process simulator; and
training the fabrication model using the plurality of designs and the plurality of simulated structures.

18. The computer-implemented method of claim 15, wherein training the fabrication model includes:
receiving a plurality of designs, wherein the plurality of designs are configured to generate physical devices having outputs that indicate morphological transformations introduced during fabrication;
receiving a plurality of performance metrics for physical devices fabricated by the fabrication system using the plurality of designs;
determining amounts of the morphological transformations introduced by the fabrication system based on the plurality of performance metrics;
generating a plurality of predicted structures based on the plurality of designs and the determined amounts of the morphological transformations; and
training the fabrication model using the plurality of designs and the plurality of predicted structures.

19. The computer-implemented method of claim 11, wherein the fabrication system is configured to implement a photolithography process.

20. The computer-implemented method of claim 11, wherein the physical device is a photonic device.
